(19) United States
(12) Patent Application Publication
(10) Pub. No.: US 2026/0324076 A1
(43) Pub. Date: Oct. 15, 2026

(54) ARRAY SUBSTRATE, DISPLAY PANEL AND DISPLAY DEVICE

(71) Applicants: Beijing BOE Technology Development Co., Ltd., Beijing (CN); BOE Technology Group Co., Ltd., Beijing (CN)

(72) Inventors: Jinchao ZHANG, Beijing (CN); Tianmin ZHOU, Beijing (CN); Binbin TONG, Beijing (CN); Lizhong WANG, Beijing (CN); Ce NING, Beijing (CN); Kun YANG, Beijing (CN)

(21) Appl. No.: 18/995,988

(22) PCT Filed: Dec. 15, 2023
(86) PCT No.: PCT/CN2023/139142

§ 371 Date: Jan. 17, 2025

(51) Int. Cl. H10D 86/40; H10D 86/60; H10K 59/121

(52) U.S. Cl. CPC H10D 86/441; H10D 86/60; H10K 59/1213

(57) ABSTRACT

Embodiments of the present disclosure provide an array substrate, a display panel and a display device. The array substrate includes: a substrate; a first active layer in the display region and on a side of the substrate; gate electrode structures in the display region and on a side of the first active layer facing away from the substrate; where the gate electrode structure includes an auxiliary gate electrode; an orthographic projection of the auxiliary gate electrode on the substrate has an overlapping region with an orthographic projection of the first active layer on the substrate, and a thickness of the auxiliary gate electrode in a direction perpendicular to the substrate ranges from 20 nm to 200 nm.

### CROSS-REFERENCE TO RELATED APPLICATIONS

The present disclosure is a National Stage of International Application No. PCT/CN2023/139142, filed on Dec. 15, 2023, the entire content of which is incorporated herein by reference.

### TECHNICAL FIELD

The present disclosure relates to the field of semiconductor technology, and in particular to an array substrate, a display panel and a display device.

### BACKGROUND

With the rise of the concept of meta-universe, the Virtual Reality (VR) headset products as port devices have attracted much attention. At present, there are Micro Organic Light Emitting Displays (Micro OLED) products on the market with good effects, but Micro OLED products are difficult to be popularized because of the high cost and difficult process.

### SUMMARY

Embodiments of the present disclosure provide an array substrate, a display panel, and a display device. The display panel includes: a substrate; a first active layer on a side of the substrate; and a gate electrode structure on a side of the first active layer facing away from the substrate; where the gate electrode structure includes an auxiliary gate electrode, an orthographic projection of the auxiliary gate electrode on the substrate has an overlapping region with an orthographic projection of the first active layer on the substrate, and a thickness of the auxiliary gate electrode in a direction perpendicular to the substrate ranges from 20 nm to 200 nm.

In a possible implementation, the array substrate further includes: a plurality of gate lines extending in a first direction, a plurality of auxiliary gate lines extending in the first direction, and a plurality of data lines main bodies of which extend in a second direction; where an orthographic projection of the plurality of auxiliary gate lines on the substrate has an overlapping region with an orthographic projection of the plurality of gate lines on the substrate; and the gate electrode structure further includes: a gate electrode portion; the gate line includes the gate electrode portion, and the auxiliary gate line includes the auxiliary gate electrode; an orthographic projection of the auxiliary gate electrode on the substrate covers an orthographic projection of the gate electrode portion on the substrate, and covers at least one of regions on two sides of the gate electrode portion in the second direction; and a thickness of the gate electrode portion in the direction perpendicular to the substrate is greater than a thickness of the auxiliary gate electrode in the direction perpendicular to the substrate, and a ratio of the thickness of the gate electrode portion in the direction perpendicular to the substrate to the thickness of the auxiliary gate electrode in the direction perpendicular to the substrate ranges from 1 to 20.

In a possible implementation, a width al of the auxiliary gate electrode in the second direction satisfies a following relational formula: 1.5≤a1/a2≤2, where a2 represents a width of the gate electrode portion in the second direction.

In a possible implementation, the width al of the auxiliary gate electrode in the second direction satisfies a following relational formula: 0.5 μm≤|a1−a2|≤1.5 μm.

In a possible implementation, the auxiliary gate line includes: a first auxiliary portion, and a second auxiliary portion electrically connected to the first auxiliary portion; where the second auxiliary portion of an N^{th} auxiliary gate line is on a side of the first auxiliary portion of the N^{th} auxiliary gate line facing an (N+1)^{th} auxiliary gate line, where N is a positive integer; and an orthographic projection of the first auxiliary portion of the N^{th} auxiliary gate line on the substrate coincides with an orthographic projection of the N^{th} gate line on the substrate, and an orthographic projection of the second auxiliary portion of the N^{th} auxiliary gate line on the substrate does not overlap with the orthographic projection of the N^{th} gate line on the substrate.

In a possible implementation, the N^{th} auxiliary gate line has a first outer edge facing away from the (N+1)^{th} gate line, and the N^{th} gate line has a second outer edge facing away from the (N+1)^{th} gate line, where N is a positive integer; and the first outer edge coincides with the second outer edge.

In a possible implementation, the N^{th} auxiliary gate line has a first outer edge facing away from the (N+1)^{th} gate line, and the N^{th} gate line has a second outer edge facing away from the (N+1)^{th} gate line; and the second outer edge is on a side of the first outer edge facing away from the (N+1)^{th} gate line.

In a possible implementation, the array substrate further includes: a first electrode on a side of the gate electrode structure facing away from the substrate, a first insulating layer between the first electrode and the first active layer, and a second insulating layer between the first insulating layer and the first active layer; the first active layer includes: a first active portion, a second active portion, and a third active portion between the first active portion and the second active portion; and an orthographic projection of the second active portion on the substrate overlaps with a part of an orthographic projection of the data line on the substrate; and the first insulating layer is provided with a first via hole, and the first electrode is electrically connected to the first active portion at least through the first via hole; and the second insulating layer is provided with a third via hole, and the data line is electrically connected to the second active portion at least through the third via hole.

In a possible implementation, the N^{th} gate line has a third outer edge facing the (N+1)^{th} gate line, and the N^{th} gate line satisfies a following relational formula: b1>b2>0, where b1 represents a distance between an orthographic projection of the third outer edge of the N^{th} gate line on the substrate and an orthographic projection of a center point of the first via hole on the substrate in the second direction, and b2 represents a distance between an orthographic projection of the second outer edge of the N^{th} gate line on the substrate and an orthographic projection of a center point of the third via hole on the substrate in the second direction.

In a possible implementation, the N^{th} gate line has a third outer edge facing the (N+1)^{th}gate line, and the N^{th} gate line satisfies a following relational formula: b3>b4>0, where b3 represents a minimum distance between an orthographic projection of the third outer edge of the N^{th} gate line on the substrate and an orthographic projection of the first via hole on the substrate in the second direction, and b4 represents a minimum distance between an orthographic projection of the second outer edge of the N^{th} gate line on the substrate and an orthographic projection of the third via hole on the substrate in the second direction.

In a possible implementation, an area of an orthographic projection of the first via hole on the substrate is greater than an area of an orthographic projection of the third via hole on the substrate.

In a possible implementation, the auxiliary gate line is provided with a convex portion protruding in the second direction; and an orthographic projection of the convex portion on the substrate has an overlapping region with the orthographic projection of the first active layer on the substrate.

In a possible implementation, the array substrate further includes: a first electrode on a side of the gate electrode structure facing away from the substrate, and a first insulating layer between the first electrode and the first active layer; the first active layer includes: a first active portion; the first insulating layer is provided with a first via hole, and the first electrode is electrically connected to the first active portion at least through the first via hole; and in a direction parallel to the first direction, a minimum distance between the first via hole and the convex portion is greater than or equal to 0.

In a possible implementation, the array substrate further includes: a second insulating layer between the first insulating layer and the first active layer; the first active layer further includes: a second active portion, and a third active portion between the first active portion and the second active portion; an orthographic projection of the second active portion on the substrate overlaps with a part of an orthographic projection of the data line on the substrate; and the second insulating layer is provided with a third via hole, and the data line is electrically connected to the second active portion at least through the third via hole; and in the direction parallel to the first direction, a minimum distance between the third via hole and the convex portion is greater than or equal to 0.

In a possible implementation, an orthographic projection of the first via hole on the substrate is within an orthographic projection of a region defined by the gate lines and the data lines that are intersected on the substrate, and the first electrode is electrically connected to the first active layer through the first via hole.

In a possible implementation, the second insulating layer is provided with a second via hole; and the array substrate further includes: a connecting electrode between the first electrode and the first active layer, where a part of the connecting electrode is on a side of the first insulating layer facing away from the substrate and is in contact with the first electrode, and the first electrode is electrically connected to the first active layer through the connecting electrode at the second via hole and the first via hole.

In a possible implementation, an orthographic projection of the second via hole on the substrate is within an orthographic projection of a region defined by the gate lines and the data lines that are intersected on the substrate.

In a possible implementation, an orthographic projection of the first via hole on the substrate and an orthographic projection of the second via hole on the substrate are between the orthographic projection of the N^{th} gate line on the substrate and an orthographic projection of the (N+1)^{th} gate line on the substrate, and in a direction perpendicular to the first direction, the orthographic projection of the first via hole on the substrate is on a side of the orthographic projection of the second via hole on the substrate facing away from the N^{th} gate line, where N is a positive integer.

In a possible implementation, the connecting electrode includes: a first connecting sub-electrode between the second insulating layer and the first insulating layer, and a second connecting sub-electrode between the first electrode and the first insulating layer; a part of the first connecting sub-electrode is at a bottom of the second via hole and is in contact with the first active layer at the bottom of the second via hole, and another part of the first connecting sub-electrode extends outwardly to a bottom of the first via hole on a side of the second insulating layer facing away from the substrate and is in contact with the second connecting sub-electrode at the bottom of the first via hole; and a part of the second connecting sub-electrode is at the bottom of the first via hole and is in contact with the first connecting sub-electrode at the bottom of the first via hole, and another part of the second connecting sub-electrode extends outwardly to a side of the first insulating layer facing away from the substrate and is in contact with the first electrode.

In a possible implementation, the array substrate further includes: a third insulating layer filled within the first via hole, where a segment difference between a surface of the third insulating layer facing away from the substrate and a surface of the first insulating layer facing away from the substrate is less than 0.2 μm.

In a possible implementation, an orthographic projection of the first via hole on the substrate covers an orthographic projection of the second via hole on the substrate; and one end of the connecting electrode is lapped in direct contact with the first active layer, and another end of the connecting electrode is lapped in direct contact with the first electrode.

In a possible implementation, the array substrate further includes: a third insulating layer filled within the second via hole and the first via hole, where a segment difference between a surface of the third insulating layer facing away from the substrate and a surface of the first insulating layer facing away from the substrate is less than 0.2 μm.

In a possible implementation, the array substrate further includes: a first gate electrode layer and a first source-drain electrode layer; where the first gate electrode layer includes the plurality of gate lines; the first source-drain electrode layer includes the plurality of data lines; where the first active layer further includes: a second active portion, and a third active portion connecting the first active portion to the second active portion; and an orthographic projection of the second active portion on the substrate overlaps with a part of an orthographic projection of the data line on the substrate; and the array substrate further includes a gate drive circuit in a non-display region, and the gate drive circuit includes: a first drive active layer, a first drive gate electrode, and a first drive source-drain electrode.

In a possible implementation, an orthographic projection of the gate electrode structure on the substrate covers at least a part of an orthographic projection of the third active portion on the substrate.

In a possible implementation, the third active portion includes: an interleaved portion, an orthographic projection of the interleaved portion on the substrate coincides with an orthographic projection of the gate electrode portion on the substrate; and the orthographic projection of the gate electrode structure on the substrate at least covers the orthographic projection of the interleaved portion on the substrate.

In a possible implementation, the auxiliary gate electrode is on a side of the gate electrode portion facing the substrate.

In a possible implementation, the auxiliary gate electrode is on a side of the gate electrode portion facing away from the substrate.

In a possible implementation, the gate electrode structure includes: a gate electrode portion; the auxiliary gate electrode is on two sides of the gate electrode portion in the second direction; and an orthographic projection of the gate electrode portion on the substrate does not overlap with an orthographic projection of the auxiliary gate electrode on the substrate.

In a possible implementation, a maximum spacing of the orthographic projection of the auxiliary gate electrode on the substrate in the second direction is greater than or equal to a maximum spacing of the orthographic projection of the gate electrode portion on the substrate in the second direction.

In a possible implementation, the gate line extends from a first end of the gate line to a second end of the gate line in the first direction; and the first active layer includes a first active group and a second active group alternatively arranged in the second direction; the first active group includes: first active patterns extending in a third direction and sequentially arranged in the first direction, the first active patterns each include a first active portion, a second active portion, and a third active portion, and an angle formed by the first active pattern with the gate line towards the first end is an acute angle; and the second active group includes: second active patterns extending in a fourth direction and sequentially arranged in the first direction, the second active patterns each include a first active portion, a second active portion, and a third active portion, and an angle formed by the second active pattern with the gate line towards the first end is an obtuse angle.

In a possible implementation, the gate line extends from a first end of the gate line to a second end of the gate line in the first direction; and the first active portion, the second active portion, and the third active portion all extend in the second direction, and angles formed by the first active portion, the second active portion, and the third active portion with the gate line towards the first end are right angles ..

In a possible implementation, the gate line extends from a first end of the gate line to a second end of the gate line in the first direction; and a first active portion and a second active portion both extend in the second direction, an extension line of the first active portion does not coincide with an extension line of the third active portion, and an angle formed by at least a part of the third active portion with the gate line towards the first end is an acute angle.

In a possible implementation, the first active portion, the second active portion, and the third active portion all extend in the first direction, and where a gap is between the orthographic projection of the first active layer on the substrate and the orthographic projection of the gate line on the substrate; and the gate electrode structure includes: the auxiliary gate electrode on a side of the first active layer facing away from the substrate, the auxiliary gate electrode extends in the second direction, and the orthographic projection of the auxiliary gate electrode the substrate covers an orthographic projection of the third active portion on the substrate and covers a part of the orthographic projection of the gate line on the substrate.

In a possible implementation, the first gate electrode layer is on a side of the first active layer facing the substrate; the gate line further includes a gate line branch portion extending in the second direction; and the orthographic projection of the auxiliary gate electrode on the substrate covers an orthographic projection of the gate line branch portion on the substrate.

In a possible implementation, a material of the auxiliary gate electrode includes: indium tin oxide, indium-doped zinc oxide, fluorine-doped tin oxide, aluminum-doped zinc oxide, or indium-doped cadmium oxide.

In a possible implementation, the data line includes: a first data portion and a second data portion extending in the second direction and alternatively arranged in the second direction, and a third data portion connecting the first data portion to the second data portion and extending in the first direction, where an extension line of the first data portion does not coincide with an extension line of the second data portion.

In a possible implementation, the array substrate further includes: a common electrode on a side of the first electrode facing away from the substrate; the common electrode includes: first common electrode portions extending in the first direction, and second common electrode portions extending in the second direction; an orthographic projection of the first common electrode portions on the substrate covers the orthographic projection of the gate line on the substrate, and an orthographic projection of the second common electrode portions on the substrate covers the orthographic projection of the data line on the substrate; and an orthographic projection of the first via hole on the substrate is within an orthographic projection of a region defined by the first common electrode portions and the second common electrode portions that are intersected on the substrate.

Embodiments of the present disclosure further provide a display panel, including the array substrate provided by the embodiments of the present disclosure.

Embodiments of the present disclosure further provide a display device, including the display panel provided by the embodiments of the present disclosure.

### BRIEF DESCRIPTION OF FIGURES

FIG. 1A is a first schematic diagram of a top view of an array substrate provided by an embodiment of the present disclosure.

FIG. 1B is a schematic diagram of a single film layer of a first active layer in FIG. 1A.

FIG. 1C is a schematic diagram of a single film layer of a gate line layer in FIG. 1A.

FIG. 1D is a schematic diagram of a single film layer of data lines in FIG. 1A.

FIG. 1E is a schematic diagram of a first connecting sub-electrode in FIG. 1A.

FIG. 1F is a schematic diagram of a second connecting sub-electrode and an outer contour of a first electrode in FIG. 1A.

FIG. 2A is a first schematic diagram of a cross-sectional view along a dashed line E1F1 in FIG. 1A.

FIG. 2B is a schematic diagram of a cross-sectional view at two via holes provided by an embodiment of the present disclosure.

FIG. 2C is another schematic diagram of a cross-sectional view at two via holes provided by an embodiment of the present disclosure.

FIG. 3 is a second schematic diagram of a top view of an array substrate provided by an embodiment of the present disclosure.

FIG. 4 is a schematic diagram of a cross-sectional view along a dashed line E2F2 in FIG. 3.

FIG. 5A is a first schematic diagram of a cross-sectional view of an array substrate provided by an embodiment of the present disclosure.

FIG. 5B is a second schematic diagram of a cross-sectional view of an array substrate provided by an embodiment of the present disclosure.

FIG. 6 is a third schematic diagram of a cross-sectional view of an array substrate provided by an embodiment of the present disclosure.

FIG. 7 is a fourth schematic diagram of a cross-sectional view of an array substrate provided by an embodiment of the present disclosure.

FIG. 8 is a fifth schematic diagram of a cross-sectional view of an array substrate provided by an embodiment of the present disclosure.

FIG. 9A is a third schematic diagram of a top view of an array substrate provided by an embodiment of the present disclosure.

FIG. 9B is a fourth schematic diagram of a top view of an array substrate provided by an embodiment of the present disclosure.

FIG. 9C is a fifth a schematic diagram of a top view of an array substrate provided by an embodiment of the present disclosure.

FIG. 9D is a sixth schematic diagram of a top view of an array substrate provided by an embodiment of the present disclosure.

FIG. 9E is a seventh schematic diagram of a top view of an array substrate provided by an embodiment of the present disclosure.

FIG. 9F is an eighth schematic diagram of a top view of an array substrate provided by an embodiment of the present disclosure.

FIG. 9G is a ninth schematic diagram of a top view of an array substrate provided by an embodiment of the present disclosure.

FIG. 10 is a tenth schematic diagram of a top view of an array substrate provided by an embodiment of the present disclosure.

FIG. 11 is an eleventh schematic diagram of a top view of an array substrate provided by an embodiment of the present disclosure.

FIG. 12A is a schematic diagram of a cross-sectional view along a dashed line E6F6 in FIG. 12B.

FIG. 12B is a twelfth schematic diagram of a top view of an array substrate provided by an embodiment of the present disclosure.

FIG. 13A is a schematic diagram of a cross-sectional view along a dashed line E7F7 in FIG. 13B.

FIG. 13B is a thirteenth schematic diagram of a top view of an array substrate provided by an embodiment of the present disclosure.

FIG. 14A is a fourteenth schematic diagram of a top view of an array substrate provided by an embodiment of the present disclosure.

FIG. 14B is a schematic diagram of a single film layer of a common electrode in FIG. 14A.

FIG. 15 is a sixth schematic diagram of a cross-sectional view of an array substrate provided by an embodiment of the present disclosure.

FIG. 16 is a seventh schematic diagram of a cross-sectional view of an array substrate provided by an embodiment of the present disclosure.

FIG. 17 is an eighth schematic diagram of a cross-sectional view of an array substrate provided by an embodiment of the present disclosure.

FIG. 18 is a ninth schematic diagram of a cross-sectional view of an array substrate provided by an embodiment of the present disclosure.

FIG. 19 is a tenth schematic diagram of a cross-sectional view of an array substrate provided by an embodiment of the present disclosure.

FIG. 20 is an eleventh schematic diagram of a cross-sectional view of an array substrate provided by an embodiment of the present disclosure.

FIG. 21 is a schematic diagram of a fabrication process of an array substrate provided by an embodiment of the present disclosure.

FIG. 22 is a schematic diagram of a fabrication process of an array substrate provided by an embodiment of the present disclosure.

FIG. 23 is a schematic diagram of a transfer characteristic curve of a transistor with an auxiliary gate electrode of a thickness that is 400 Å.

FIG. 24 is a schematic diagram of a transfer characteristic curve of a transistor with an auxiliary gate electrode of a thickness that is 700 Å.

FIG. 25 is a schematic diagram of a transfer characteristic curve of a transistor with an auxiliary gate electrode of a thickness that is 1000 Å.

FIG. 26 is a schematic diagram of a transfer characteristic curve of a transistor with an auxiliary gate electrode of a thickness that is 1350 Å.

### DETAILED DESCRIPTION

Embodiments of the present disclosure will be described in detail below in conjunction with the accompanying drawings. The embodiments may be implemented in a plurality of different forms. Those ordinary skilled in the art can readily appreciate the fact that the manners and contents can be transformed into one or more forms without departing from the purpose of the present disclosure and its scope. Accordingly, the present disclosure should not be construed to be limited only to the contents documented in the following embodiments. The embodiments and the features in the embodiments in the present disclosure may be combined with each other in any combination without conflict.

In the accompanying drawings, the size of one or more constituent elements, or the thickness or region of a layer is sometimes exaggerated for clarity. Accordingly, one manner of the present disclosure is not necessarily limited to that size, and the shapes and sizes of the components in the accompanying drawings do not reflect true proportions. Furthermore, the accompanying drawings schematically illustrate desirable examples, and the one manner of the present disclosure is not limited to the shapes or values, etc., shown in the accompanying drawings.

The ordinal terms such as “first”, “second”, “third”, etc., in the specification are provided to avoid confusion of constituent elements, and are not intended to be limited in terms of quantity. The “plurality” in this disclosure may include two or more.

In the specification, for convenience, “middle”, “up”, “down”, “front”, “back”, “vertical”, “horizontal”, “top”, “bottom”, “inside”, “outside”, and other words and phrases indicating orientation or positional relationships are used to illustrate the positional relationships of the constituent elements with reference to the accompanying drawings, which are intended only for the purpose of facilitating the description of the present specification and simplifying the description, and are not intended to indicate or imply that the device or element referred to must have a particular orientation, or to be constructed and operated in a particular orientation, and therefore are not to be construed as a limitation to the present disclosure. The positional relationships of the constituent elements are appropriately changed according to the orientation in which the constituent elements are described. Accordingly, the words and phrases are not limited to those described in the specification, and may be appropriately replaced depending on the circumstances.

In the specification, the terms “mounted”, “connected”, and “coupled” are to be broadly construed unless otherwise expressly provided and limited. For example, the connection may be fixed, or removable, or integrally connected, or mechanically connected, or electrically connected, or may be directly connected, or indirectly connected through an intermediate member, or connected within two elements. To those ordinary skill in the art, the meaning of the above terms in the present disclosure may be understood as the case.

In the specification, “electrically connected” includes a situation in which the constituent elements are connected together by an element having a certain electrical action. There is no special limitation on the term “element having a certain electrical action” as long as the transmission of electrical signals between the connected constituent elements is possible. Examples of “elements having a certain electrical action” include not only electrodes and wiring, but also switching elements such as transistors, resistors, inductors, capacitors, and other elements having one or more functions.

In this specification, a transistor is a component that includes at least three terminals: a gate electrode (gate), a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region is a region through which the current flows predominantly.

Additionally, the gate electrode of the transistor may be referred to as a control electrode. The functions of the “source electrode” and the “drain electrode” are sometimes interchanged when transistors of opposite polarity are used, or when the direction of the current changes in circuit operation. Therefore, in the specification, the “source electrode” and the “drain electrode” are interchangeable.

In the specification, “parallel” refers to a state in which an angle formed by two straight lines is −10° or more and 10° or less, and therefore, a state in which an angle is −5° or more and 5° or less can be included. In addition, “perpendicular” refers to a state in which an angle formed by the two straight lines is 80° or more and 100° or less, and therefore, a state in which an angle is 85° or more and 95° or less can be included.

In this specification, a triangle, rectangle, trapezoid, pentagon, or hexagon, etc., is not strictly defined, but can be an approximate triangle, rectangle, trapezoid, pentagon, or hexagon, etc., and there can be some small deformations due to tolerance, and there can be a leading angle, an arc edge, and deformations.

In the specification, “film” and “layer” can be interchangeable. For example, the term “conductive layer” can be changed to “conductive film”. Similarly, “insulating film” can be replaced with “insulating layer”.

In the specification, the terms “about” and “substantially” refer to a situation in which process and measurement errors are permissible without strictly limiting the boundaries. In the specification, “substantially” the same” can be a case where the difference between values is 10% or less.

For ultra-high resolution display products, the aperture rate of the pixel region can be directly and effectively improved by optimizing the line width of the wiring and the size of the via hole, thereby optimizing the display effect. However, at the same time, the impact of the reduction of the channel length also poses a corresponding challenge to the short-channel characteristics of the transistor in the display backplane. When the channel length is less than 2 μm, the oxide transistor will appear more obvious short-channel effect, which mainly includes the Drain Induced Barrier Lowering (DIBL) effect and the diffusion effect of conductivization doping, both of which affect the characteristics of the oxide transistor, resulting in characteristics that cannot be ensured.

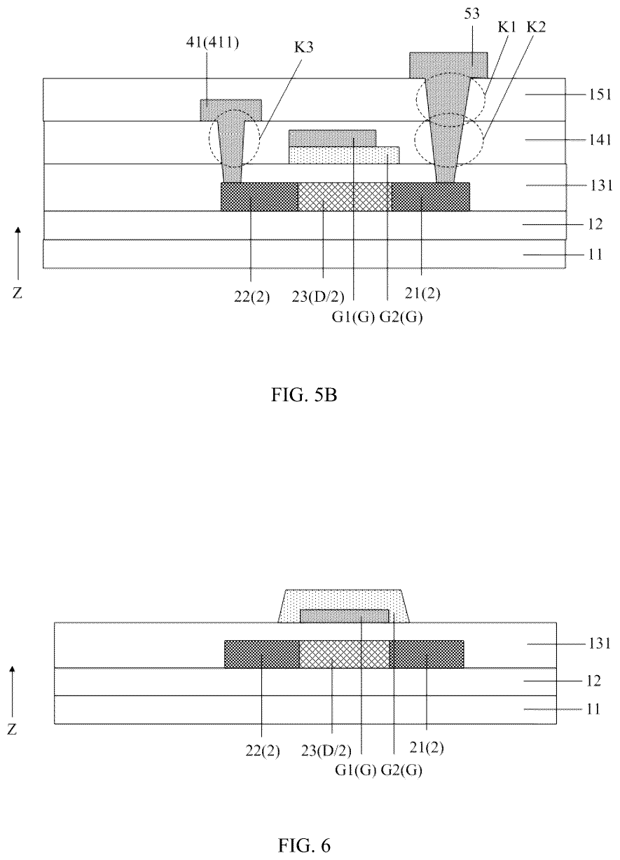

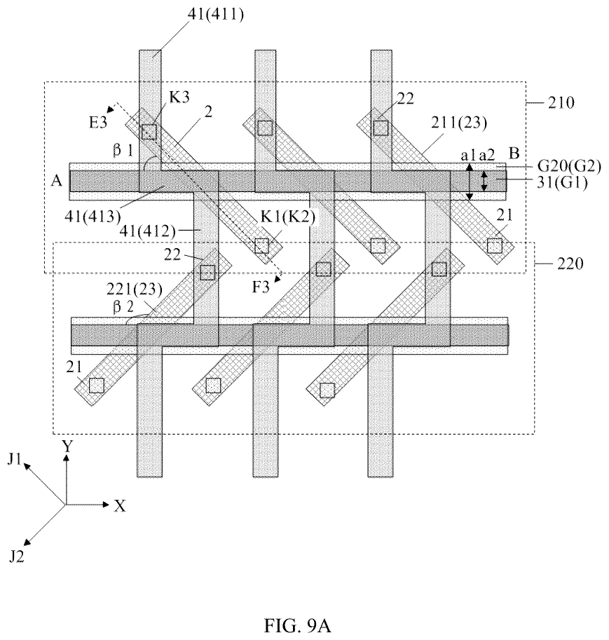

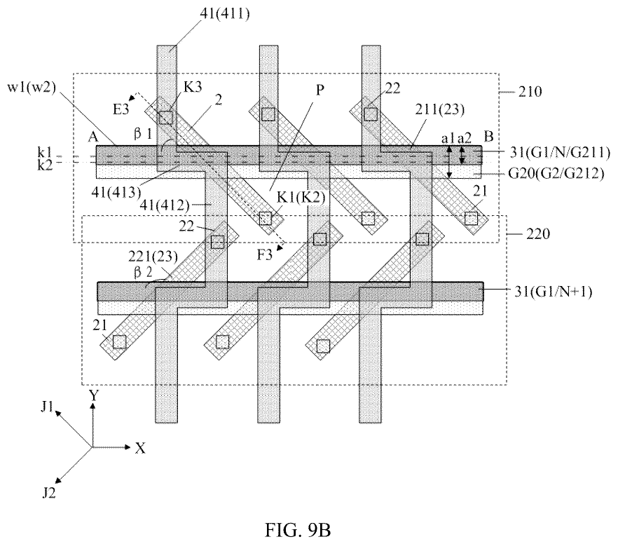

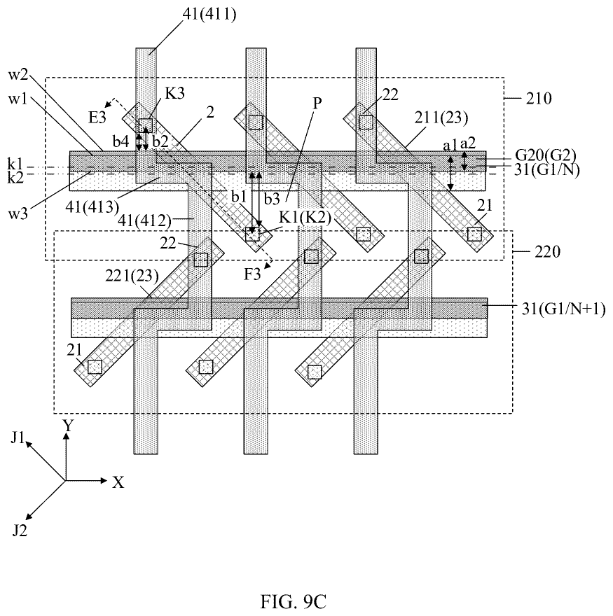

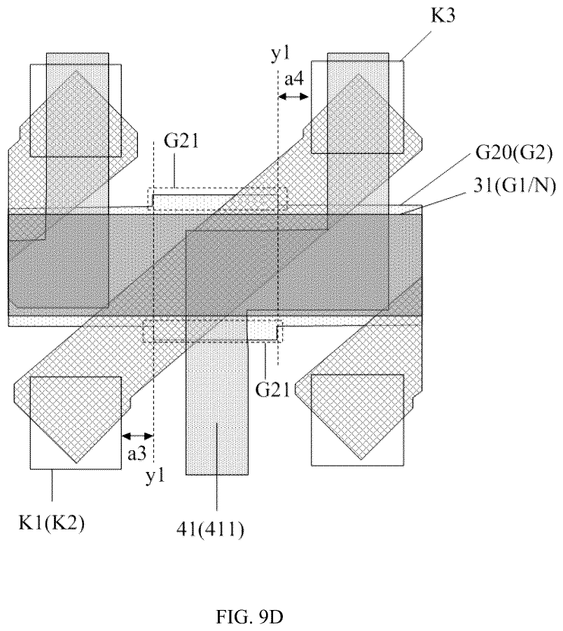

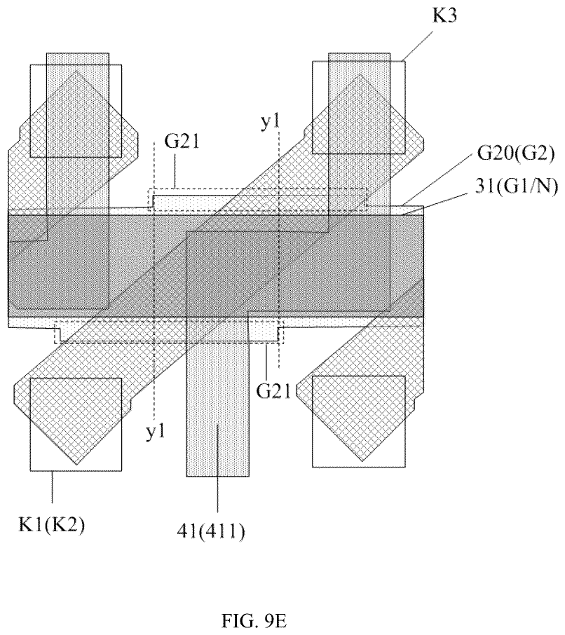

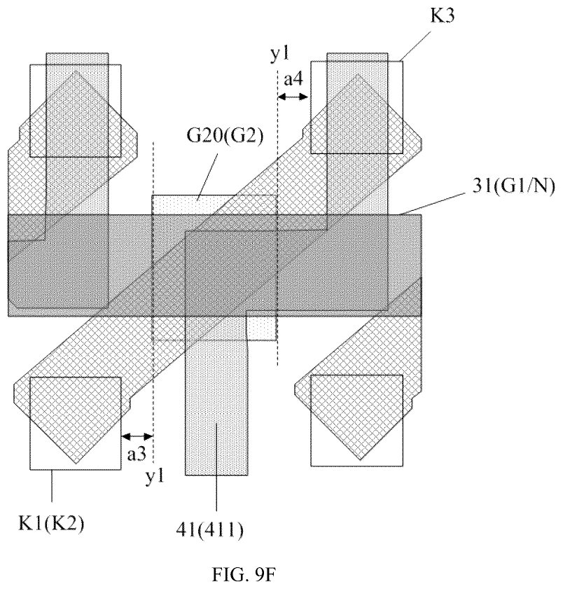

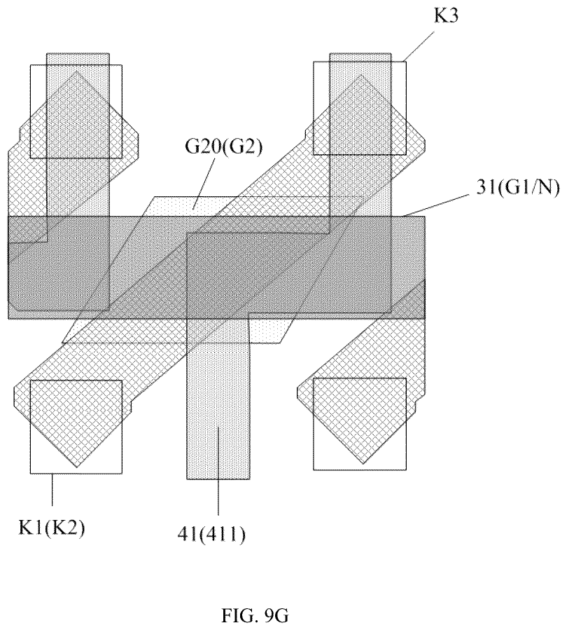

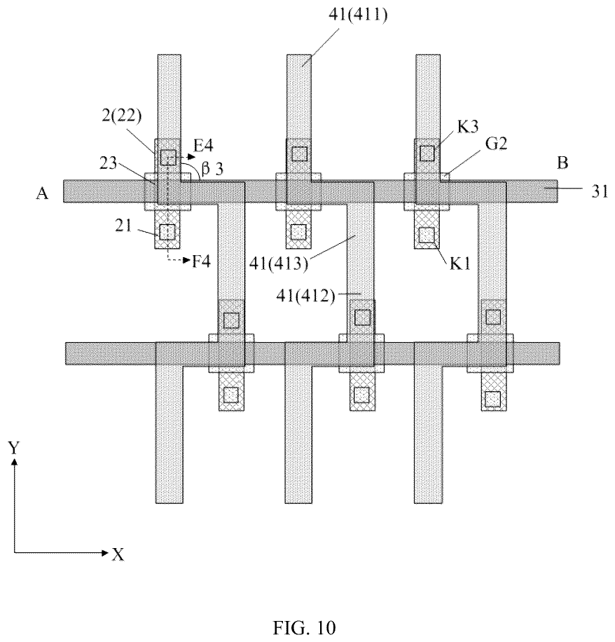

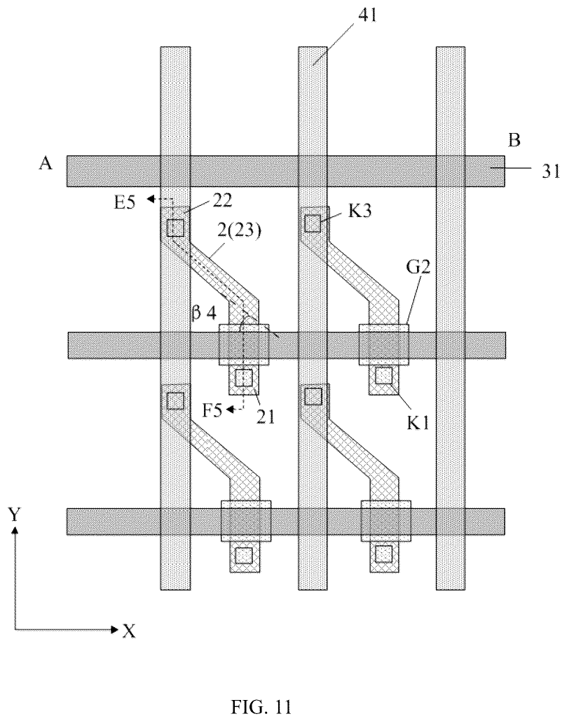

In view of this, embodiments of the present disclosure provide an array substrate, as shown in FIGS. 5A, 5B, 6-8, 9A-9F, 10, 11, 12A, 12B, 13A, and 13B. FIG. 5A may be a cross-sectional view along the dashed line E3F3 in FIG. 9A, FIG. 10 along the dashed line E4F4, and along the dashed line E5F5 in FIG. 11. FIG. 5B may be a cross-sectional view along the dashed line E3F3 in FIG. 9B. A direction of the Z-axis in the cross-sectional view may be a direction perpendicular to the substrate. The array substrate includes: a substrate 11; a first active layer 2 in a display region and on a side of the substrate 11; gate electrode structures G in a display region and on a side of the first active layer 2 facing away from the substrate 11. The gate electrode structure G at least includes an auxiliary gate electrode G2. An orthographic projection of the auxiliary gate electrode G2 on the substrate 11 has an overlapping region with an orthographic projection of the first active layer 2 on the substrate 11, and the auxiliary gate electrode G2 has a thickness in a direction perpendicular to the substrate 11 in a range of 20 nm to 200 nm.

In the embodiment of the present disclosure, the gate electrode structure G includes the auxiliary gate electrode G2, which, on the one hand, can block the injection of a part of ions during subsequent conductivization for the first active layer, extend a channel length of the first active layer, ensure the characteristics of the oxide transistor, and eliminating the drain induced barrier lowering effect and the diffusion effect of conductivization doping. The thickness of the auxiliary gate electrode G2 in the direction perpendicular to the substrate 11 ranges from 20 nm to 200 nm, which ensures that the auxiliary gate electrode G2 has a certain blocking effect on the injected ions for the subsequent conductivation, and also ensures that it is not too thick, leading to the problem that it cannot be patterned to remove in case of the direct crystallization.

In a possible implementation, the thickness of the auxiliary gate electrode G2 in the direction perpendicular to the substrate 11 may range from 30 nm to 100 nm. In a possible implementation, the thickness of the auxiliary gate electrode G2 in the direction perpendicular to the substrate 11 may range from 40 nm to 70 nm. In a possible implementation, the thickness of the auxiliary gate electrode G2 in the direction perpendicular to the substrate 11 may range from 50 nm to 60 nm. In one possible implementation, the thickness of the auxiliary gate electrode G2 in the direction perpendicular to the substrate 11 may be 40 nm, 50 nm, 60 nm, 70 nm, 80 nm, 90 nm, 100 nm, 110 nm, 120 nm, 130 nm, 135 nm, 140 nm, 150 nm, 160 nm, 170 nm, 180 nm, 190 nm, or 200 nm.

In a possible implementation, referring to FIGS. 5A, 9A, the array substrate further includes: a plurality of gate lines 31 extending along a first direction X, a plurality of auxiliary gate lines G20 extending along the first direction X, and a plurality of data lines 41 main bodies of which extend along the second direction Y. An orthographic projection of the auxiliary gate lines G20 on the substrate 11 has an overlapping region with an orthographic projection of the gate lines 31 on the substrate 11.

The gate electrode structure G further includes: a gate electrode portion G1. The gate line 31 includes a gate electrode portion G1. The auxiliary gate line G20 includes the auxiliary gate electrode G2. An orthographic projection of the auxiliary gate electrode G2 on the substrate 11 covers an orthographic projection of the gate electrode portion G1 on the substrate 11, and covers at least one of regions on two sides of the gate electrode portion G1 in the second direction Y.

In a possible implementation, a thickness of the gate electrode portion G1 in the direction perpendicular to the substrate 11 is greater than a thickness of the auxiliary gate electrode G2 in the direction perpendicular to the substrate 11, and a ratio of the thickness of the gate electrode portion G1 in the direction perpendicular to the substrate 11 to the thickness of the auxiliary gate electrode G2 in the direction perpendicular to the substrate 11 ranges from 1 to 20. In a possible implementation, the ratio of the thickness of the gate electrode portion G1 in the direction perpendicular to the substrate 11 to the thickness of the auxiliary gate electrode G2 in the direction perpendicular to the substrate 11 may be 1, 1.2, 1.4, 1.6, 1.8, 2, 4, 6, 8, 10, 12, 14, 16, 18, or 20.

In a possible implementation, the thickness of the gate electrode portion G1 in the direction perpendicular to the substrate 11 may be 280 nm, 300 nm, 320 nm, 340 nm, 360 nm, 380 nm, 400 nm, 450 nm, or 500 nm.

It should be noted that the main body of the data line 41 is along the second direction Y, which can be understood that the data line 41 as a whole extends along the second direction Y throughout the array substrate, but may be bent at localized locations.

In a possible implementation, referring to FIG. 9A, a width al of the auxiliary gate electrode G2 in the second direction Y satisfies the following relational formula: 1.5≤a1/a2≤2. Where a2 represents a width of the gate electrode portion G1 in the second direction Y. In the embodiments of the present disclosure, 1.5≤a1/a2, which can ensure a larger aperture region by reducing the line width of the gate line 31; a1/a2<2, which can ensure the characteristics of the oxide transistor and eliminate a bad risk of shorting (Gate-Drain Short, GDS) between the gate line 31 and the data line 41 caused by the overlap of the first via hole K1 and/or the third via hole K3 with the gate line 31 since the first via hole K1 and/or the third via hole K3 are too close to the gate line 31 in the ultra-high PPI structure.

In a possible implementation, referring to FIG. 9A, the width al of the auxiliary gate electrode G2 in the second direction satisfies the following relational formula: 0.5 μm≤|a1−a2|≤1.5 μm. By this way, the larger aperture region is ensured by reducing the line width of the gate line 31, and a bad risk of shorting (Gate-Drain Short, GDS) between the gate line 31 and the data line 41 since the first via hole K1 and/or the third via hole K3 are too close to the gate line 31 in the ultra-high PPI structure.

In a possible implementation, the width a2 of the gate electrode portion G1 in the second direction Y may be 1.8 μm, 1.9 μm, 2 μm, 2.1 μm, or 2.2 μm; the width al of the auxiliary gate electrode G2 in the second direction may be 2.8 μm, 2.9 μm, 3 μm, 3.1 μm, or 3.2 μm; and |a1-a2|=0.8 μm, 0.9 μm, 1.0 μm, 1.1 μm, 1.2 μm. In a possible implementation, the gate electrode portion G1 has the width a2 of 2 μm in the second direction Y, and the auxiliary gate electrode G2 is compensated for 0.5 μm on one side.

In a possible implementation, referring to FIGS. 5B and 9B, the auxiliary gate line G20 includes: a first auxiliary portion G211, and a second auxiliary portion G212 electrically connected to the first auxiliary portion G211. The second auxiliary portion G212 of an Nth auxiliary gate line G20 is on a side of the first auxiliary portion G211 of the N^{th} auxiliary gate line G20 towards an (N+1)^{th} auxiliary gate line G20, where N is a positive integer.

An orthographic projection of the first auxiliary portion G211 of the N^{th} auxiliary gate line G20 on the substrate 11 coincides with an orthographic projection of the N^{th} gate line 31 on the substrate 11, and an orthographic projection of the second auxiliary portion G212 of the Nth auxiliary gate line G20 on the substrate 11 does not overlap with the orthographic projection of the N^{th} gate line 31 on the substrate 11. In the embodiment of the present disclosure, the second auxiliary portion G212 of the N^{th} auxiliary gate line G20 can be located on the side of the first auxiliary portion G211 of the N^{th} auxiliary gate line G20 towards the (N+1)^{th} auxiliary gate line G20 by moving the gate line 31 upward. Because a hole depth of the first via hole K1 is larger and a size of the first via hole K1 is larger, and the overlapping of the first via hole K1 with the gate line 31 is more prone to occur due to the process error. By moving the gate line 31 upward, the distance between the gate line 31 and the first via hole K1 can be enlarged, thereby reducing the chance of the overlapping of the gate line 31 with the first via hole K1 and eliminating the poor GDS.

In a possible implementation, the (N+1)^{th} gate line 31 may be the next gate line 31 of the N^{th} gate line 31 in a gate electrode signal scanning direction. That is, when each gate line 31 is loaded with a gate electrode signal, the N^{th} gate line 31 is loaded with the gate electrode signal before the (N+1)^{th} gate line 31.

In a possible implementation, referring to FIG. 9B, the gate line 31 has a first axis k1 extending along the first direction X, and the gate line 31 is symmetrical about the first axis k1. The auxiliary gate line G20 has a second axis k2 extending along the first direction X, and the auxiliary gate line G20 is symmetrical about the second axis k2. The first axis k1 of the N^{th} gate line 31 is located on a side of the second axis k2 of the N^{th} auxiliary gate line 31 facing away from the (N+1)^{th} gate line 31.

In a possible implementation, referring to FIG. 9B, the N^{th} auxiliary gate line G20 has a first outer edge w1 facing away from the (N+1)^{th} gate line 31, and the N^{th} gate line 31 has a second outer edge w2 facing away from the (N+1)^{th} gate line 31. The first outer edge w1 coincides with the second outer edge w2.

In a possible implementation, referring to FIG. 9C, the N^{th} auxiliary gate line G20 has a first outer edge w1 facing away from the (N+1)^{th} gate line 31, and the N^{th} gate line 31 has a second outer edge w2 facing away from the (N+1)^{th} gate line 31. The second outer edge w2 is located on a side of the first outer edge w1 facing away from the (N+1)^{th} gate line 31.

In a possible implementation, referring to FIGS. 5A and 9A, the array substrate further includes: first electrodes 53 on a side of the gate electrode structure G facing away from the substrate 11, and a first insulating layer 151 between the first electrodes 53 and the first active layer 2, and a second insulating layer 141 between the first insulating layer 151 and the first active layer 2.

The first active layer 2 includes: a first active portion(s) 21, a second active portion(s) 22, and a third active portion(s) 23 between the first active portion 21 and the second active portion 22. The first active portion 21 is in the light-transmitting region P, and an orthographic projection of the second active portion 22 on the substrate 11 overlaps with a part of an orthographic projection of the data line 41 on the substrate 11.

The first insulating layer 151 has first via holes K1. The first electrode 53 is electrically connected to the first active portion 21 at least through the first via hole K1. The second insulating layer 141 has third via holes K3. The data line 41 is electrically connected to the second active portion 22 at least through the third via hole K3.

In a possible implementation, the first electrode 53 is electrically connected to the first active portion 21 at least through the first via hole K1, which can be understood that the first electrode 53 is not directly electrically connected to the first active portion 21, but electrical connection between the two can also be realized through other via holes as well as other structures. For example, as shown in FIG. 5A, the second insulating layer 141 can also have second via holes K2. The first electrode 53 can be electrically connected to the first active layer 2 through the first via hole K1 and the second via hole K2.

In a possible implementation, referring to FIG. 9C, the N^{th} gate line has a third outer edge facing the (N+1)^{th} gate line, and the N^{th} gate line satisfies the following relational formula: b1>b2>0. Where b1 represents a minimum distance between an orthographic projection of the third outer edge w3 of the N^{th} gate line 31 on the substrate 11 and an orthographic projection of a center point of the first via hole K1 on the substrate 11 in the second direction Y, and b2 represents a minimum distance between the orthographic projection of the second outer edge w2 of the N^{th} gate line 31 on the substrate 11 and an orthographic projection of a center point of the third via hole K3 on the substrate 11 in the second direction Y.

In a possible implementation, referring to FIG. 9C, the N^{th} gate line 31 has a third outer edge w3 facing the (N+1)^{th} gate line, and the N^{th} gate line 31 satisfies the following relational formula: b3>b4>0. Where b3 represents a minimum distance between the orthographic projection of the third outer edge w3 of the N^{th} gate line 31 on the substrate 11 and the orthographic projection of the first via hole K1 on the substrate 11 in the second direction Y, and b2 represents a minimum distance between the orthographic projection of the second outer edge w2 of the N^{th} gate line 31 on the substrate 11 and the orthographic projection of the third via hole K3 on the substrate 11 in the second direction Y.

In a possible implementation, referring to FIG. 5A, an area of the orthographic projection of the first via hole K1 on the substrate 11 is larger than an area of the orthographic projection of the third via hole K3 on the substrate 11.

In a possible implementation, referring to FIG. 9D, the auxiliary gate line G20 has a convex portion G21 protruding along the second direction Y; and an orthographic projection of the convex portion on the substrate 11 has an overlapping region with the orthographic projection of the first active layer 2 on the substrate 11. In the embodiment of the present disclosure, the auxiliary gate line G20 has a convex portion(s) G21 protruding in the second direction Y. The orthographic projection of the convex portion G21 on the substrate 11 has an overlapping region with the orthographic projection of the first active layer 2 on the substrate 11. That is, the convex portion G21 has a wider width along the second direction Y in the channel region where the orthographic projection of the convex portion G21 on the substrate overlaps with the orthographic projection of the first active layer 2 on the substrate, so as to ensure the characteristics of the oxide transistor. The auxiliary gate electrode G2 is indented at the position corresponding to the first via hole K1 and/or the third via hole K3 to avoid the first via hole K1 and/or the third via hole K3 thereby reducing the chances of the gate line 31 overlapping with the first via hole K1 and/or the third via hole K3, and eliminating the poor GDS.

In a possible implementation, in conjunction with FIGS. 5A and 9D, the array substrate further includes: the first electrodes 53 disposed on the side of the gate electrode structures G facing away from the substrate 11, and a first insulating layer 151 between the first electrodes 53 and the first active layer 2. The first active layer 2 includes: the first active portion 21; the first active portion 21 is in the light-transmitting region P. The first insulating layer 151 has first via holes K1. The first electrode 53 is electrically connected to the first active portion 21 through the first via hole K1. A minimum distance a3 between the first via hole K1 and the convex portion G21 is greater than or equal to 0 in a direction parallel to the first direction X.

In a possible implementation, in conjunction with FIGS. 5A and 9D, the convex portion G21 has a first convex portion edge y1 extending along the second direction Y. An extension line of an orthographic projection of the first convex portion edge y1 on the substrate 11 does not overlap with the orthographic projection of the first via hole K1 on the substrate 11.

In a possible implementation, in conjunction with FIGS. 5A and 9D, the array substrate further includes: a second insulating layer 141 between the first insulating layer 151 and the first active layer 2. The first active layer 2 further includes: second active portions 22, and third active portions 23 each between the first active portion 21 and the second active portion 22. The orthographic projection of the second active portion 22 on the substrate 11 overlaps with a part of the orthographic projection of the data line 41 on the substrate 11. The second insulating layer 141 has third via holes K3. The data line 41 is electrically connected to the second active portion 22 through the third via hole K3. A minimum distance a4 between the third via hole K3 and the convex portion G 21 is greater than or equal to 0 in a direction parallel to the first direction X.

In a possible implementation, in conjunction with FIGS. 5A and 9D, the extension line of the orthographic projection of the first convex portion edge y1 on the substrate 11 does not overlap with the orthographic projection of the third via hole 3K on the substrate.

In a possible implementation, referring to FIG. 9E, the convex portion G21 may extend in the first direction X all the way into the region where the first via hole K1 and the third via hole K3 are located. For example, as shown in FIG. 9E, the orthographic projection of the convex portion G21 on the substrate 11 may cover the overlapping edges of the orthographic projection of the first active layer 2 on the substrate with the orthographic projection of the gate line 31 on the substrate, and thus the auxiliary gate electrode G2 has the wider width along the second direction Y in the entire channel region where the orthographic projection of the auxiliary gate electrode on the substrate overlaps with the orthographic projection of the first active layer 2 on the substrate, so as to ensure the characteristics of the oxide transistor.

In a possible implementation, as shown in FIGS. 9F and 9G, a block-shaped auxiliary gate electrode G2 may be provided in a region of the orthographic projection of the first active layer 2 on the substrate overlapping with the orthographic projection of the gate line 31 on the substrate, and thus the auxiliary gate electrode G2 has the wider width along the second direction Y over the entire channel region where the orthographic projection of the auxiliary gate electrode G2 on the substrate overlaps with the orthographic projection of the first active layer 2 on the substrate, thereby ensuring the characteristics of the oxide transistor. In a possible implementation, the block-shaped auxiliary gate electrode G2 may be rectangular, as shown in FIG. 9F. In a possible implementation, the block-shaped auxiliary gate electrode G2 may be a parallelogram, as shown in FIG. 9G.

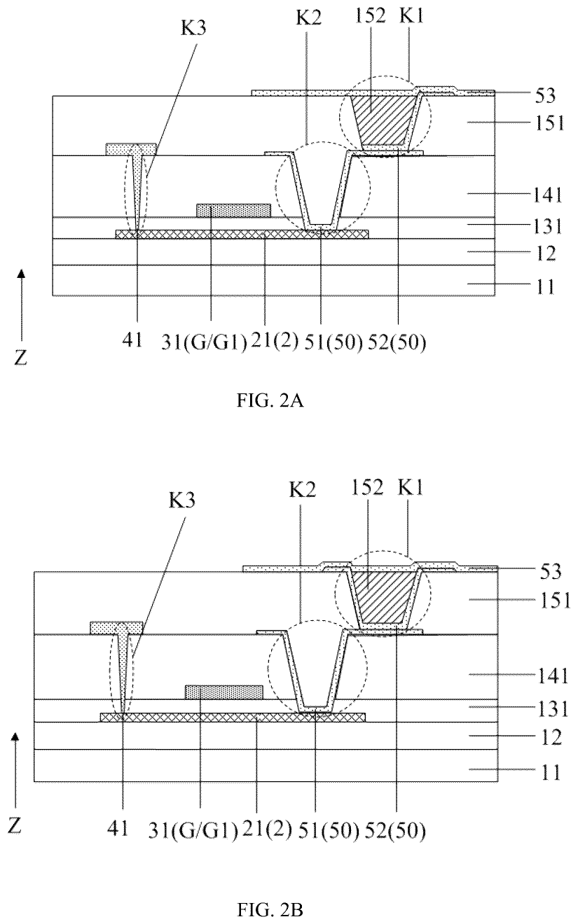

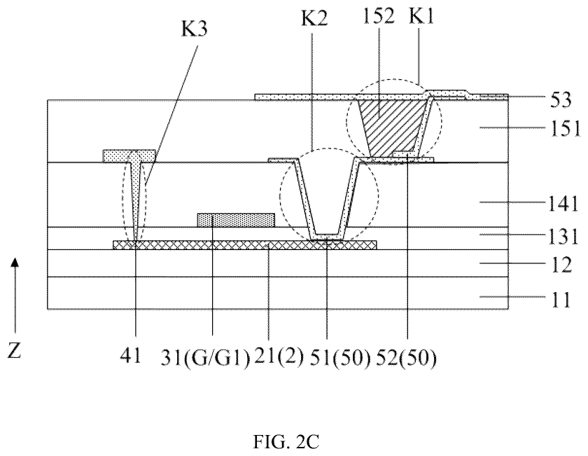

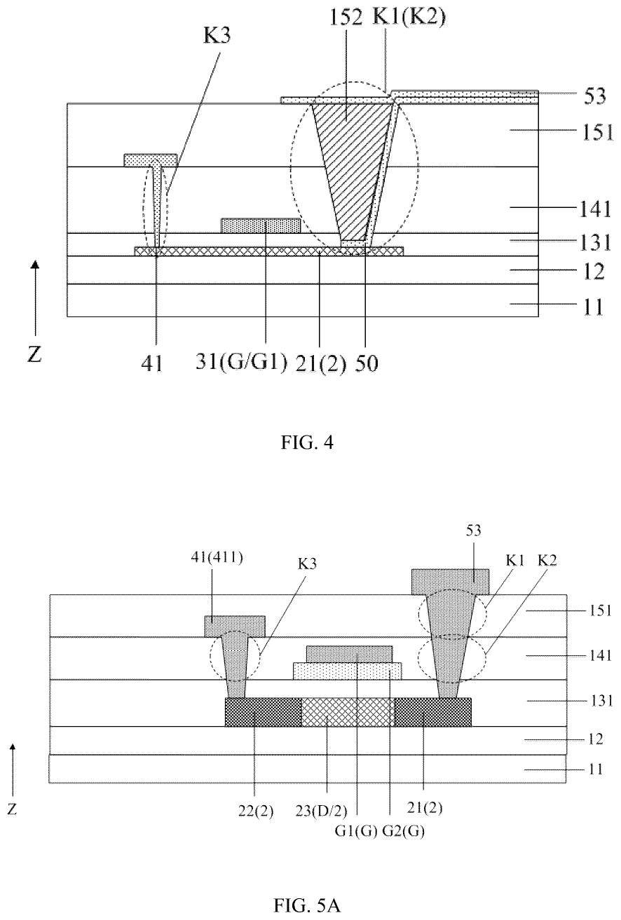

In a possible implementation, referring to FIGS. 5A and 4, the first via hole K1 may penetrate through the first insulating layer 151 and the second insulating layer 141, realizing the electrical connection between the first electrode 53 and the first active layer 2. In another possible implementation, referring to FIGS. 2A-2C, the first via hole K1 may penetrate through the first insulating layer 151, the second insulating layer 141 may also have the second via hole(s) K2, and the first electrode 53 may electrically connected with the first active layer 2 through the first via hole K1 and the second via hole K2.

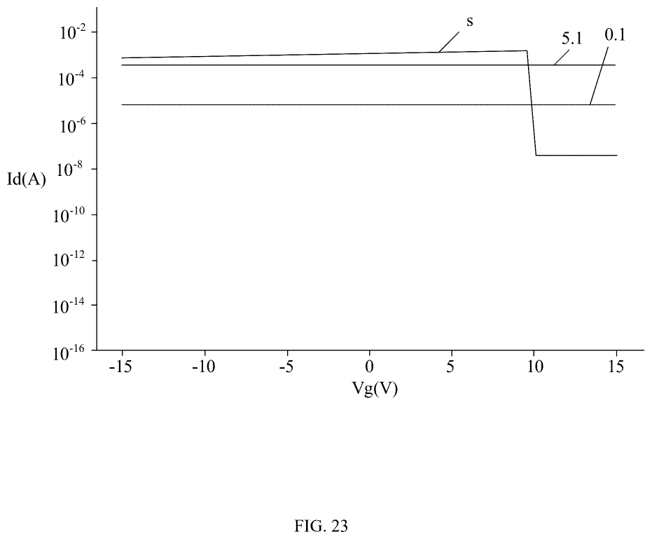

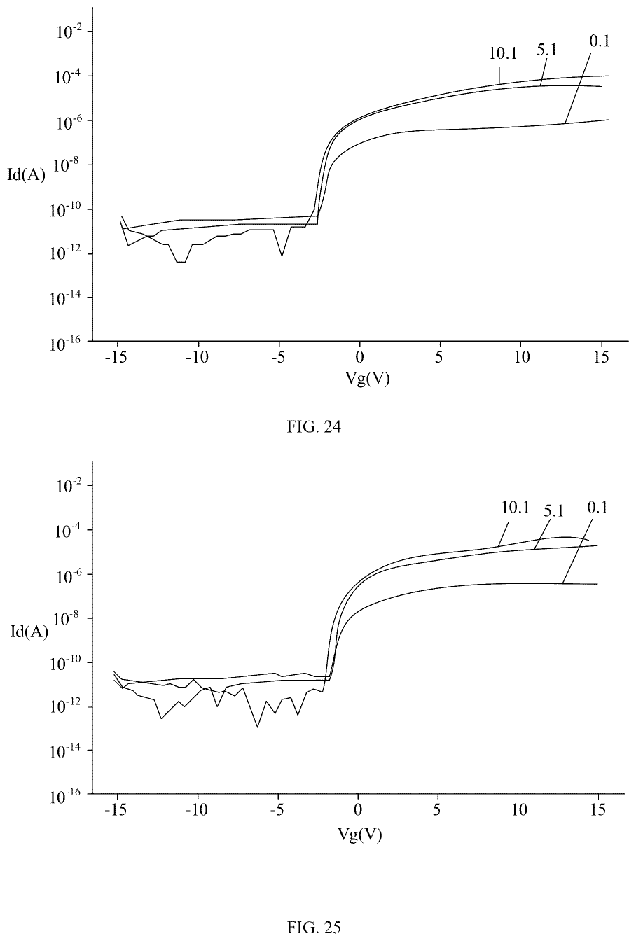

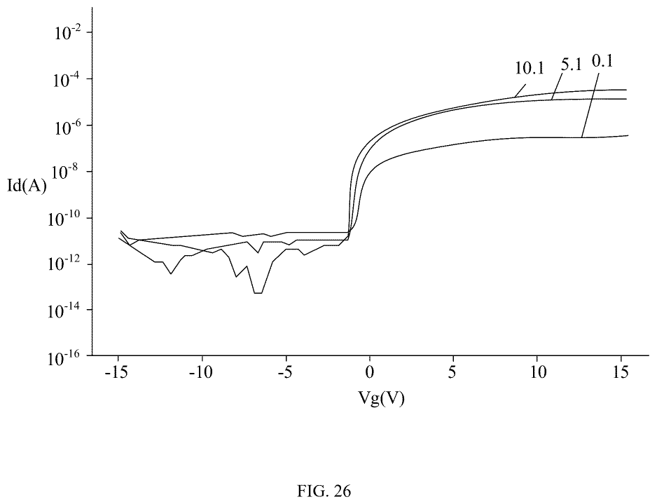

In a possible implementation, referring to FIGS. 23, 24, 25, and 26, where FIGS. 23, 24, 25, and 26 are schematic diagrams of transfer characteristic curves corresponding to the array substrate structure shown in FIG. 5A by taking a1−a2 being 1 μm and the source electrode of the transistor being loaded with voltages Vd of 0.1 V, 5.1 V, and 10.1 V as an example. Horizontal coordinates represent a gate voltage Vg of the transistor with unit V, and vertical coordinates represent a drain current Ig of the transistor with unit A. The thickness of the auxiliary gate electrode G2 corresponding to FIG. 23 is 400 Å, the thickness of the auxiliary gate electrode G2 corresponding to FIG. 24 is 700 Å, the thickness of the auxiliary gate electrode G2 corresponding to FIG. 25 is 1,000 Å, and the thickness of the auxiliary gate electrode G2 corresponding to FIG. 26 is 1,350 Å. According to FIGS. 23, 24, 25, and 26, it can be seen that when the thickness of the auxiliary gate electrode G2 is 400 Å, the leakage current of the transistor is larger, the characteristics of the transistor are poorer, and the ion injection cannot be effectively blocked during conductivation; and when the thickness of the auxiliary gate electrode G2 is larger than 400 Å, the leakage current of the transistor is smaller, and the channel performance of the transistor can be guaranteed. Considering that the transistor performance is also affected by other factors (e.g., the line width of the gate line, the ion injection dose of the active layer, the oxygen content of the gate electrode insulating layer, etc.), the thickness of the auxiliary gate electrode G2 can range from 20 nm to 200 nm by combining various factors.

At present, the optimal choice for ultra-high PPI is the liquid crystal display (LCD) technology, because in the LCD display structure, the pixel region circuit only has one switching transistor (Thin Film Transistor, TFT), which is very conducive to realize the high PPI, but the LCD transmittance rate is low. The development for a backplane process solution with high aperture rate is required. Especially, when the PPI reaches 2000 or more, various line widths, line spacings, and via hole sizes reach the limit of the capacity of the display manufacturing equipment, and the area of the aperture region is drastically compressed, thereby requiring a new type of backplane structure to improve the backlighting efficiency.

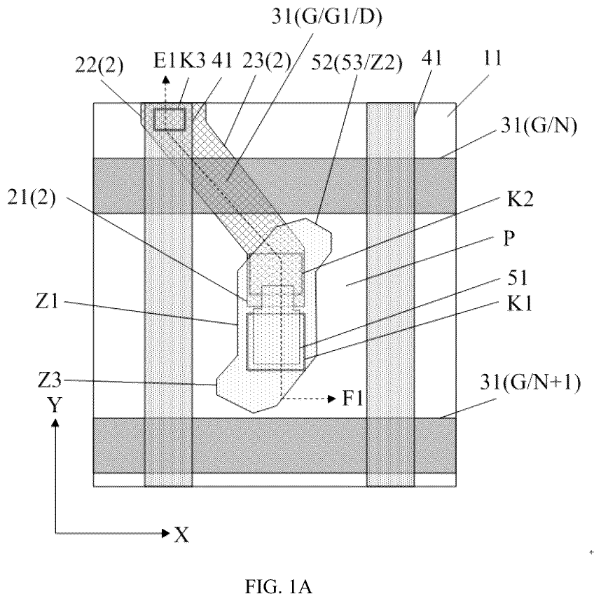

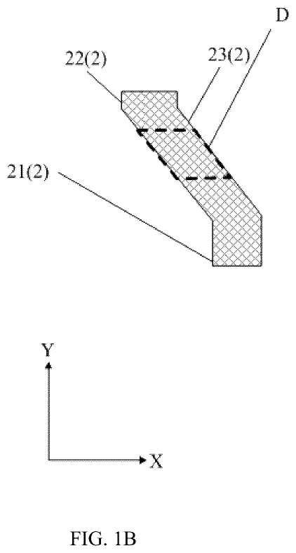

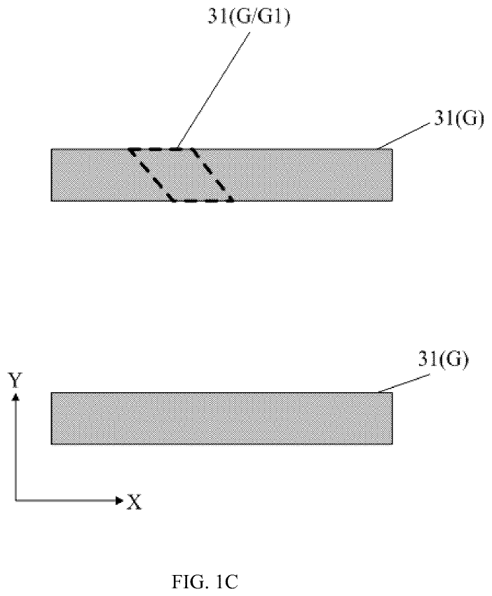

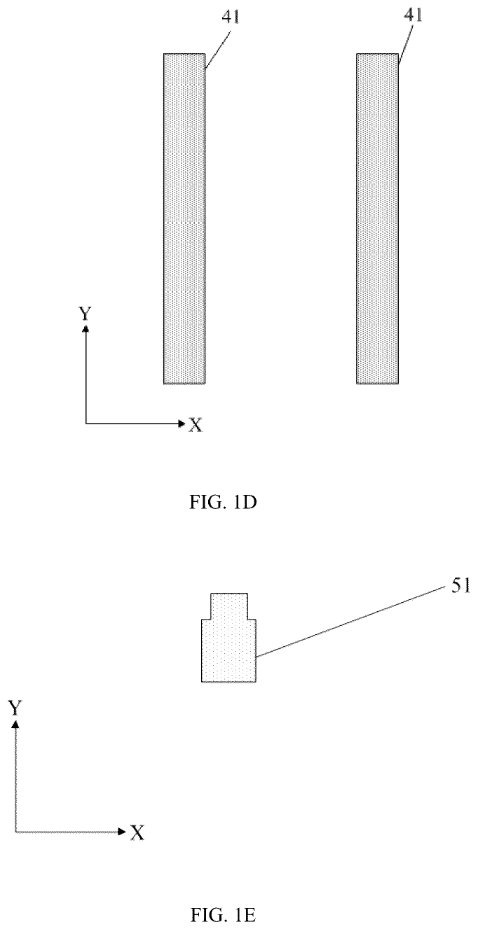

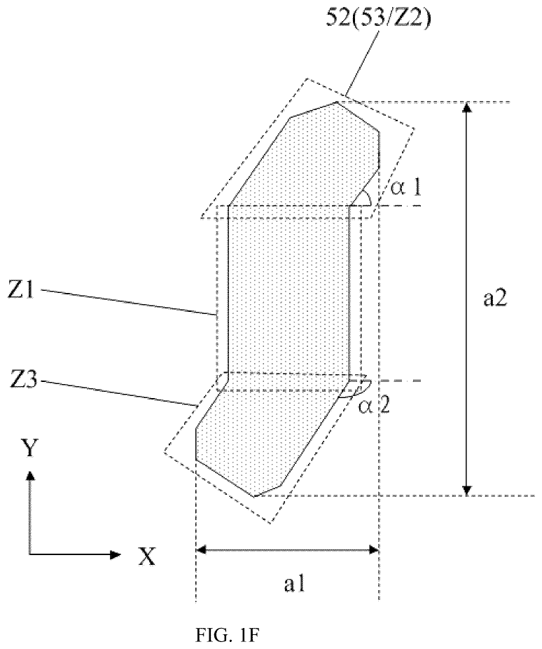

In view of this, embodiments of the present disclosure provide an array substrate, as shown in FIGS. 1A-1F, 2A, 2B, and 2C. FIG. 1B is a schematic diagram of a single film layer of a first active layer in FIG. 1A. FIG. 1C is a schematic diagram of a single film layer of a gate line layer in FIG. 1A. FIG. 1D is a schematic diagram of a single film layer of data lines in FIG. 1A. FIG. 1E is a schematic diagram of a first connecting sub-electrode in FIG. 1A. FIG. 1F is a schematic diagram of a second connecting sub-electrode and an outer contour of a first electrode in FIG. 1A. FIG. 2A is a first schematic diagram of a cross-sectional view along a dashed line E1F1 in FIG. 1A. FIG. 2B is a schematic diagram of a cross-sectional view at two via holes provided by the embodiment of the present disclosure. FIG. 2C is another schematic diagram at two via holes provided by the embodiment of the present disclosure. The array substrate has a display region and a non-display region located in a peripheral region of the display region, and the display region has a plurality of light-transmitting regions P.

The array substrate includes: first transistors (not shown in the figures) in the display region and on a side of the substrate 11, the first transistors including a first active layer 2; first electrodes 53 on a side of the first active layer 2 facing away from the substrate 11; and a first insulating layer 151, which is between the first active layer 2 and the first electrodes 53, and is in contact with the first electrodes 53, and has first via holes K1 penetrating through the first insulating layer 151. The first electrode 53 may be a pixel electrode. The orthographic projection of the first via hole K1 on the substrate 11 is within the orthographic projection of the light-transmitting region P on the substrate 11. In particular, an area of the orthographic projection of the light-transmitting region P on the substrate 11 is larger than an area of the orthographic projection of the first via hole K1 on the substrate 11. The orthographic projection of the light-transmitting region P on the substrate 11 covers the orthographic projection of the first via hole K1 on the substrate 11, so that the first electrode 53 is electrically connected to the first active layer 2 through the first via hole K1. Specifically, the first insulating layer 151 may be a first flat layer.

In the embodiments of the present disclosure, the first via hole K1 through which the first electrode 53 is electrically connected to the first active layer 2 is provided in the light-transmitting region P. Compared with that in the prior art, the first via hole K1 through the first electrode 53 is electrically connected to the first active layer 2 is provided at the location of the wiring in the non-light-transmitting region, which results in a part of a region in the first electrode used for the conductive electrical connection to the first active layer and another part of the region used for the display, whereas the region used for the conductive electrical connection located outside the light-transmitting region P cannot be used for display, thereby making an effective area of the first electrode 53 smaller, while in the embodiment of the present disclosure, the first via hole K1 through which the first electrode 53 is electrically connected to the first active layer 2 is located in the light-transmitting region P, and the first electrode 53 is not only electrically connected to the first active layer 2, but also used for display, which enlarges the effective area of the first electrode 53 and improves the liquid crystal efficiency (the deflection ability of the liquid crystal to the linearly polarized light) and enhances the light transmission rate of the array substrate.

The light-transmitting region P can be understood as a region in the array substrate where the sub-pixels are used for display. The array substrate may have a black matrix, and the black matrix may have a black matrix opening(s). The orthographic projection of the light-transmitting region P on the substrate 11 may coincide with an orthographic projection of the black matrix opening on the substrate 11. The first via hole K1 may be located in a region defined by the gate lines and the data lines that are intersected. Since the array substrate is provided with other light-impermeable structures, such as the black matrix, and a light-blocking layer on a side of the active layer towards the substrate for blocking the light to the active layer, etc., in addition to the gate lines and the data lines. The arrangement of the black matrix and the light-blocking layer further reduces the region defined by the gate lines and the data lines that are intersected to finally form the light-transmitting region P.

The array substrate may include a light-blocking structure (not shown in the figures), and the orthographic projection of the light-blocking structure on the substrate 11 does not overlap with the orthographic projection of the pixel opening region P on the substrate 11. The display substrate may include the array substrate and a color film substrate opposite to each other. The light-blocking structure may include a black matrix in the array substrate and/or the color film substrate, and the light-blocking structure may also include the light-blocking layer in the array substrate. The light-blocking layer may be a light-blocking metal layer.

In a possible implementation, referring to FIGS. 1A-1F, 2A, 2B, and 2C, the array substrate further includes: a second insulating layer 141 between the first insulating layer 151 and the first active layer 2. The second insulating layer 141 has second via holes K2. The array substrate further includes: connecting electrodes 50 between the first electrodes 53 and the first active layer 2. A part of the connecting electrode 50 is on a side of the first insulating layer 151 facing away from the substrate 11 and is in contact with the first electrode 53, and the first electrode 53 is electrically connected to the first active layer 2 through the connecting electrode 50 at the second via hole K2 and the first via hole K1. The second insulating layer 141 may be a first interlayer dielectric layer.

In a possible implementation, referring to FIGS. 1A-1F, 2A, 2B, and 2C, the orthographic projection of the second via hole K2 on the substrate 11 is within the orthographic projection of the light-transmitting region P on the substrate 11. An area of the orthographic projection of the light-transmitting region P on the substrate 11 is larger than an area of the orthographic projection of the second via hole K2 on the substrate 11. The orthographic projection of the light-transmitting region P on the substrate 11 covers the orthographic projection of the second via hole K2 on the substrate 11. In a possible implementation, the second via holes K2 may also be not located in the light-transmitting region P; or, the second via holes K2 are partially located in the light-transmitting region P and partially located outside the light-transmitting region P.

In a possible implementation, referring to FIGS. 1A-1F, FIG. 2A, FIG. 2B, and FIG. 2C, a center point of the orthographic projection of the first via hole K1 on the substrate 11 does not coincide with a center point of the orthographic projection of the second via hole K2 on the substrate 11. The array substrate includes: a first gate electrode layer. The first gate electrode layer includes a plurality of gate lines 31 extending in the first direction. The orthographic projections of the first via hole K1 and the second via hole K2 on the substrate 11 are located between the orthographic projection of the N^{th} gate line 31 and the orthographic projection of the (N+1)^{th} gate line 31 on the substrate. In the direction perpendicular to the first direction X, the orthographic projection of the first via hole K1 on the substrate 11 is on the side of the orthographic projection of the second via hole K2 on the substrate 11 facing way from the Nth gate line 31, where N is a positive integer.

It should be noted that the N^{th} gate line and the (N+1)^{th} gate line are two adjacent gate lines in the array substrate loaded with the scanning signals in sequence, and the (N+1)^{th} gate line is the next gate line in the scanning direction of the scanning signal of the N^{th} gate line. That is, when the scanning signal is loaded to the array substrate, the N^{th} gate line is loaded with the scanning signal first, and then the (N+1)^{th} gate line is loaded with the scanning signal. That is, the N^{th} gate line is loaded with the scanning signal before the (N+1)^{th} gate line.

In a possible implementation, as shown in FIGS. 1A-1F, 2A, 2B, and 2C, the orthographic projection of the first via hole K1 on the substrate 11 does not overlap with the orthographic projection of the second via hole K2 on the substrate 11. The connecting electrode 50 include: a first connecting sub-electrode 51 between the second insulating layer 141 and the first insulating layer 151, and a second connecting sub-electrode 52 between the first electrode 53 and the first insulation layer 151. A part of the first connecting sub-electrode 51 is at a bottom of the second via hole K2 and is in contact with the first active layer 2 at the bottom of the second via hole K2. Another part of the first connecting sub-electrode 51 extends outwardly to a bottom of the first via hole K1 on a side of the second insulation layer 141 facing away from the substrate 11 and is in contact with the second connecting sub-electrode 52 at the bottom of the first via hole K1. A part of the second connecting sub-electrode 52 is at the bottom of the first via hole K1 and is in contact with the first connecting sub-electrode 51 at the bottom of the first via hole K1. Another part of the second connecting sub-electrode 52 extends outwardly to a side of the first insulating layer 151 facing away from the substrate 11 and is in contact with the first electrode 53. In the embodiment of the present disclosure, the array substrate includes the first via holes K1, and the second via holes K2. That is, the first via holes K1 are fabricated in the first insulating layer 151, and the second via holes K2 are fabricated in the second insulating layer 141. The first electrode 53 is electrically connected to the first active layer 2 through a two-step etching process. Compared with that it is more difficult to etch when the first electrode 53 is electrically connected to the first active layer 2 through a single via hole directly, the first electrode 53 is electrically connected to the first active layer 2 through two via holes in the embodiments of the present disclosure, which is less difficult in process fabrication and easier to be realized.

As shown in FIGS. 1A-1F, 2A, 2B, and 2C, a part of the first connecting sub-electrode 51 is at the bottom of the second via hole K2 to realize the contact lap connection with the first active layer 2, and another part of the first connecting sub-electrode 51 covers the sidewall of the second via hole K2, climbs to extend outwardly above the second insulating layer 141 and extends to the bottom of the first via hole K1 to realize the electrical connection with the second connecting sub-electrode 52. The orthographic projection of the first connecting sub-electrode 51 on the substrate 11 may cover a part of the orthographic projection of the second via hole K2 on the substrate 11, or may cover all of the orthographic projection of the second via hole K2 on the substrate 11.

A part of the second connecting sub-electrode 52 is at the bottom of the hole of the first via hole K1 and is in contact with the first connecting sub-electrode 51, and another part of the second connecting sub-electrode 52 covers the sidewall of the first via hole K1, climbs to extend outwardly to the periphery of the first via hole K1 and covers above the first insulating layer 151 to realize the contact lap connection with the first electrode 53. The orthographic projection of the second connecting sub-electrode 52 on the substrate 11 may cover a part of the orthographic projection of the first via hole K1 on the substrate 11, or may cover all of the orthographic projection of the first via hole K1 on the substrate 11.

The specific pattern of the second connecting sub-electrode 52 may be designed as desired. The orthographic projection of the second connecting sub-electrode 52 on the substrate 11 may be a triangle, a quadrilateral, a pentagon, a hexagon, a circle, an oval, or other irregular shape. The specific pattern of the second connecting sub-electrode 52 needs to satisfy that, on the one hand, a contact lap connection of the second connecting sub-electrode 52 with the first electrode 53 can be realized, and, on the other hand, after stacking with the first electrode 53, the overall outer contour of the two covers the orthographic projections of the first via hole K1 and the second via hole K2 on the substrate 11. In conjunction with FIG. 1F, the shape of the overall outer contour of the second connecting sub-electrode 52 and the first electrode 53 that are stacked may be in the shape of a strip, in which, a maximum length a1 in the first direction X may be smaller than a maximum length a2 in the second direction Y, and a maximum length a1 in the first direction X may be smaller than a length of the light-transmitting region P in the first direction X or a maximum length a1 in the first direction X may be equal to a length of the light-transmitting region P in the first direction X; and an extended length a2 in the second direction Y may be greater than a length of the light-transmitting region P in the second direction Y; or an extended length a2 in the second direction Y may be equal to the length of the light-transmitting region P in the second direction Y; or, an extended length a2 in the second direction Y may be less than the length of the light-transmitting region P in the second direction Y.

In a possible implementation, at the first via hole K1, the second connecting sub-electrode 52 may only cover one side of the first insulating layer 151 facing away from the substrate 11, as shown in FIG. 2A; alternatively, the second connecting sub-electrode 52 may cover an entire outer edge of the first insulating layer 151 facing away from the substrate 11, as shown in FIG. 2B. In a possible implementation, the second connecting sub-electrode 52 at the bottom of the first via hole K1 may cover all of the bottom of the first via hole K1, as shown in FIG. 2A; alternatively, the second connecting sub-electrode 52 at the bottom of the first via hole K1 may cover a part of the bottom of the first via hole K1, as shown in FIG. 2C.

As shown in FIG. 1F, the overall outer contour shape of the second connecting sub-electrode 52 and the first electrode 53 that are stacked may include: a first main body portion Z1, and a second extension portion Z2 extending from one end of the first main body portion Z1, and a third extension portion Z3 extending from the another end of the first main body portion Z1.

An extension direction of the second extension portion Z2 may be different from an extension direction of the first main body portion Z1, and an extension direction of the third extension portion Z3 may be different from the extension direction of the first main body portion Z1. The first main body portion Z1 may extend along the second direction Y. An first angle al formed by the extension direction of the second extension portion Z2 with the first direction X may range from 15° to 75°, e.g., 45°. A second angle a2 formed by the extension direction of the third extension portion Z3 with the first direction X may range from-115° to −165°, e.g., −135°. The orthographic projection of the second extension portion Z2 on the substrate 11 may not overlap with the orthographic projection of the gate line 31 on one side of the light-transmitting region P on the substrate 11. Alternatively, the orthographic projection of the second extension portion Z2 on the substrate 11 may partially overlap with the orthographic projection of the gate line 31 on one side of the light-transmitting region P on the substrate 11. The orthographic projection of the third extension portion Z3 on the substrate 11 may not overlap with the orthographic projection of the gate line 31 on another side of the light-transmitting region P on the substrate 11. The orthographic projection of the third extension portion Z3 on the substrate 11 may partially overlap with the orthographic projection of the gate line 31 on another side of the light-transmitting region P on the substrate 11. At least a part of the first main body portion Z1 is exposed to the light-transmitting region P.

In a possible implementation, referring to FIGS. 1A-1F, 2A, 2B, and 2C, the array substrate further includes: a third insulating layer 152 filled within the first via hole K1, and a surface of the third insulating layer 152 facing away from the substrate 11 has a segment difference of less than 0.2 μm from a surface of the first insulating layer 151 facing away from the substrate 11. The third insulating layer 152 may be a second flat layer. In the embodiment of the present disclosure, the array substrate further includes the third insulating layer 152 filled in the first via hole K1, which can flatten the segment difference around the first via hole K1. The segment difference between the surface of the third insulating layer 152 facing away from the substrate 11 and the surface of the first insulating layer 151 facing away from the substrate 11 is less than 0.2 μm, so as to avoid the liquid crystal orientation abnormality during the box aligning process caused by the segment difference of 0.2 μm or more and the light leakage caused by the large segment difference around the first via hole K1.

The first insulating layer 151 is a first flat layer. Due to the first insulating layer is usually thicker, the light leakage occurs when the via hole is set. In the conventional design, the via hole is set at a location where the light-blocking metal wiring is located to block the light that leaks out. In the embodiments of the present disclosure, the first via hole K1 of the first insulating layer 151 is in the light-transmitting region P, which can increase the effective area of the first electrode 53, improve the liquid crystal efficiency, and the first via hole K1 is filled in by the third insulating layer 152 to ensure that there is no light leakage caused by the segment difference.

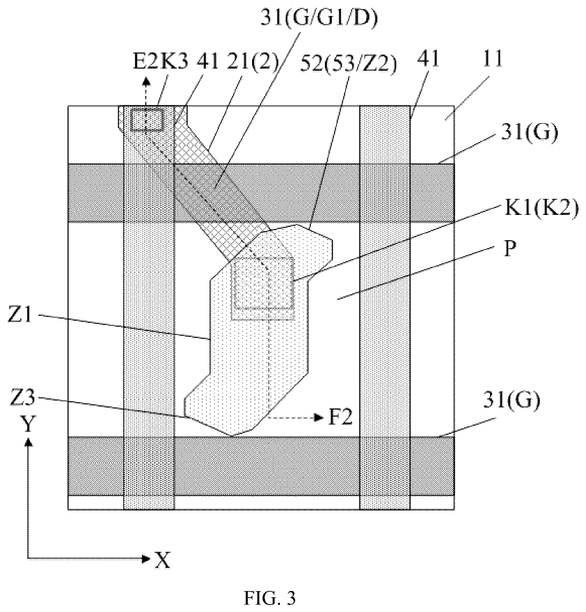

In a possible implementation, referring to FIGS. 3 and 4, FIG. 4 is a schematic diagram of a cross-sectional view along the dashed line E2F2 in FIG. 3. The orthographic projection of the first via hole K1 on the substrate 11 covers the orthographic projection of the second via hole K2 on the substrate 11. One end of the connecting electrode 50 is lapped in direct contact with the first active layer 2, and another end of the connecting electrode 50 is lapped in direct contact with the first electrode 53. The second via hole K2 and the first via hole K1 may be formed by one-step etching manner. In the disclosure embodiment, the orthographic projection of the first via hole K1 on the substrate 11 covers the orthographic projection of the second via hole K2 on the substrate 11. In a specific implementation, the first insulating layer 151 and the second insulating layer 141 may be formed by the one-step etching method, which can reduce one via hole in the light-transmitting region P, and at the same time, save the two masking processes when patterning the second insulating layer 141 and the first connecting sub-electrode 51.

In a possible implementation, referring to FIGS. 3 and 4, the array substrate further includes: a third insulating layer 152 filled within the second via hole K2 and the first via hole K1. The segment difference between the surface of the third insulating layer 152 facing away from the substrate 11 and the surface of the first insulating layer 151 facing away from the substrate 11 is less than 0.2 μm. In the embodiment of the present disclosure, the array substrate further includes: the third insulating layer 152 filled within the second via hole K2 and the first via hole K1, which can flatten the segment difference around the first via hole K1 and the second via hole K2. The segment difference between the surface of the third insulating layer 152 facing away from the substrate 11 and the surface of the first insulating layer 151 facing away from the substrate 11 is less than 0.2 μm, so as to avoid the liquid crystal orientation abnormality during the box aligning process caused by the segment difference of 0.2 μm or more and the light leakage caused by the large segment difference around the first via hole K1.

In a possible implementation, a material of the first active layer 2 includes: a rare-earth-element doped metal oxide. The material of the first active layer 2 is a metal oxide semiconductor material, and the metal oxide semiconductor material may include any one or more of indium gallium zinc oxide (IGZO), indium gallium oxide (IGO), indium gallium zinc tin oxide (IGZTO), indium zinc oxide (IZO), or rare-earth-element doped metal oxide (RE-OS). The rare-earth-element doped metal oxide may include lanthanide-doped metal oxide (LDMA). The crystallization state of the active layer material may be amorphous, partially crystalline, or polycrystalline. In the embodiment of the present disclosure, the material of the first active layer 2 is the rare-earth-element doped metal oxide. The first active layer 2 may have stable performance even when it is exposed to light, and thus it may be no need to be set up with a light-blocking layer in the light-transmitting region P, which may further improve the aperture rate of the array substrate.

In a possible implementation, referring to FIGS. 1A-4, the orthographic projection of the first electrode 53 on the substrate 11 covers orthographic projections of the first via hole K1 and the second via hole K2 on the substrate 11. Since the second connecting sub-electrode 52 is distributed in the first via hole K1 and the first connecting sub-electrode 51 is distributed in the second via hole K2, the in-hole connecting electrodes may form an electric field with an electrode layer (e.g., a common electrode layer) above the first electrode 53, which may then affect the normal deflection of the liquid crystals. In the embodiment of the present disclosure, the orthographic projection of the first electrode 53 on the substrate covers the orthographic projection of the second via hole K2 on the substrate 11, which may block the electric field in the via hole to stabilize the electric field.

In a possible implementation, referring to FIGS. 1A-4, the first active layer 2 includes: a first active portion(s) 21. The first active portion 21 is in the light-transmitting region P. The first electrode 53 is electrically connected to the first active portion 21 through the first via hole K1. In the embodiment of the present disclosure, the first active layer 2 includes the first active portion 21 in the light-transmitting region P, so as to realize the conductive electrical connection with the first electrode 53 in the light-transmitting region P.

In a possible implementation, referring to FIGS. 1A-4, the array substrate further includes: a first source-drain electrode layer. The first source-drain electrode layer includes a plurality of data lines 41 main bodies of which extend in the second direction Y. The first active layer 2 further includes: a second active portion(s) 22, and a third active portion(s) 23 connecting the first active portion 21 to the second active portion 22. The orthographic projection of the second active portion 22 on the substrate 11 overlaps with a part of the orthographic projection of the data line 41 on the substrate 11. The second insulating layer 141 further includes the third via hole K3 exposing a portion of the second active portion 22. The data line 41 is electrically connected to the second active portion 22 through the third via hole K3. In the embodiment of the present disclosure, the first active layer 2 further includes the second active portion 22 overlapping with the data line 41, and in this way, the conductive electrical connection is realized between the first active layer 2 and the data line 41.

In a possible implementation, referring to FIGS. 1A and 1C, the array substrate further includes the gate electrode structures G disposed on the side of the first active layer 2 facing away from the substrate 11. The orthographic projection of the gate electrode structure G on the substrate 11 covers at least a part of an orthographic projection of the third active portion 23 on the substrate. In a specific embodiment, the gate electrode structure G may include different structures, as described in detail hereinafter.

In a possible implementation, referring to FIGS. 1A and 1C, the gate line 31 includes the gate electrode portion G1 (as shown by the bold black line box in FIG. 1C). The third active portion 23 includes: an interleaved portion D (as shown by the bold black line box in FIG. 1B). An orthographic projection of the interleaved portion D on the substrate 11 coincides with the orthographic projection of the gate electrode portion G1 on the substrate 11. The orthographic projection of the gate electrode structure G on the substrate 11 at least covers the orthographic projection of the interleaved portion D on the substrate 11. In the structure shown in FIG. 1A, the interleaved portion D may be understood as the region, i.e., as the interleaved portion D, in the third active portion 23 that overlaps with the gate line 31, as shown in FIG. 1B.

In a possible implementation, referring to FIGS. 1A and 2A, 2B and 2C, the gate electrode structure G may only include the gate electrode portion G1.

In a possible implementation, the gate electrode structure G may also include: the gate electrode portion G1, and the auxiliary gate electrode G2. The material of the gate electrode portion G1 may be the same as the material of the gate line 31. The auxiliary gate electrode G2 may be a transparent structure. The material of the auxiliary gate electrode G2 may include: metal oxide (e.g., indium-tin oxide, indium-doped zinc oxide, fluorine-doped tin oxide, aluminum-doped zinc oxide (AZO), and indium-doped cadmium oxide).

The auxiliary gate electrode G2 may be on a side of the gate electrode portion G1 facing the substrate 11, or may be on a side of the gate electrode portion G1 facing away from the substrate 11, as described in detail below. For example, referring to FIG. 5A, which may be a cross-sectional view along the dashed line E3F3 in FIG. 9A, a cross-sectional view along the dashed line E4F4 in FIG. 10, or a cross-sectional view along the dashed line E5F5 in FIG. 11. The gate electrode structure G may include: the gate electrode portion G1, and the auxiliary gate electrode G2 on the side of the gate electrode portion G1 facing the substrate 11. The orthographic projection of the auxiliary gate electrode G2 on the substrate 11 covers the orthographic projection of the gate electrode portion G1 on the substrate 11, and covers at least one of regions on two sides of the gate electrode portion Glin the second direction Y. As shown in FIG. 5A, the orthographic projection of the auxiliary gate electrode G2 on the substrate 11 may also cover the orthographic projection of the gate electrode portion G1 on the substrate 11, and covers one of the regions on two sides of the gate electrode portion G1 in the second direction Y.

It should be noted that the first via hole shown in FIG. 5A may also be a connection mode as shown in FIGS. 2A and 4.

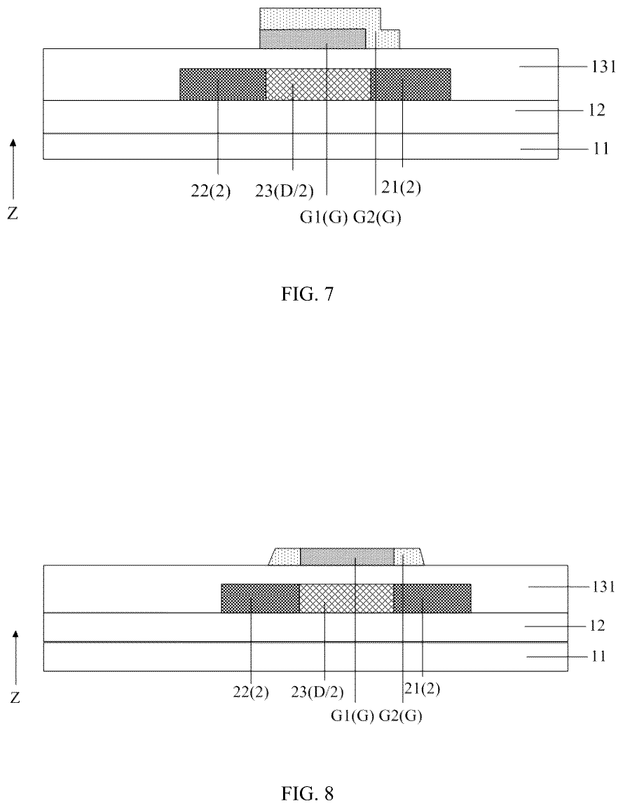

In a possible implementation, referring to FIGS. 6 and 7, the gate electrode structure G includes: the gate electrode portion G1, and the auxiliary gate electrode G2 on the side of the gate electrode portion G1 facing away from the substrate 11. The orthographic projection of the auxiliary gate electrode G2 on the substrate 11 covers the orthographic projection of the gate electrode portion G1 on the substrate 11, and covers at least one of the regions on both sides of the gate electrode portion G1 in the second direction Y. For example, referring to FIG. 6, the orthographic projection of the auxiliary gate electrode G2 on the substrate 11 covers the orthographic projection of the gate electrode portion G1 on the substrate 11, and covers the regions on both sides of the gate electrode portion G1 in the second direction Y. For example, referring to FIG. 7, the orthographic projection of the auxiliary gate electrode G2 on the substrate 11 covers the orthographic projection of the gate electrode portion G1 on the substrate 11, and covers one of the regions on both sides of the gate electrode portion Glin the second direction Y.

In a possible implementation, referring to FIG. 8, the gate electrode structure G includes: the gate electrode portion G1, and the auxiliary gate electrode G2 on both sides of the gate electrode portion G1 in the second direction Y. The orthographic projection of the gate electrode portion G1 on the substrate 11 does not overlap with the orthographic projection of the auxiliary gate electrode G2 on the substrate 11. That is, the orthographic projection of the auxiliary gate electrode G2 on the substrate 11 is on both sides of the orthographic projection of the gate electrode portion G1 on the substrate 11.

In a possible implementation, referring to FIGS. 5A-8, a maximum spacing al of the orthographic projection of the auxiliary gate electrode G2 on the substrate 11 in the second direction Y is greater than or equal to a maximum spacing a2 of the orthographic projection of the gate electrode portion G1 on the substrate 11 in the second direction. It should be noted that, for the array substrate structure shown in FIGS. 5A-7, the maximum spacing al of the orthographic projection of the auxiliary gate electrode G2 on the substrate 11 in the second direction Y can be understood as a width of the auxiliary gate electrode G2 in the second direction Y. For the array substrate structure shown in FIG. 8, the maximum spacing al of the orthographic projection of the auxiliary gate electrode G2 on the substrate 11 in the second direction Y can be understood to refer to a maximum distance between two auxiliary gate electrodes G2 in the second direction Y.

In a specific implementation, the first active layer 2 may have a variety of different pattern shapes, as specified below.

In one possible implementation, the first active layer 2 may include a plurality of diagonal linear patterns. Referring to FIG. 9A, a cross-sectional view along the dashed line E3F3 in FIG. 9A may be shown in FIG. 5A. The gate lines 31 extending from a first end A to a second end B along the first direction X. The first active layer 2 includes a first active group 210 and a second active group 220 alternatively arranged in the second direction Y. The first active group 210 includes a plurality of first active patterns 211 extending along the third direction J1 and sequentially arranged along the first direction X. The first active pattern 211 includes a first active portion 21, a second active portion 22, and a third active portion 23. An angle β1 formed by the first active pattern 211 with the gate line 31 towards the first end A is an acute angle. The second active group 220 includes: a plurality of second active patterns 221 extending along the fourth direction J2 and sequentially arranged along the first direction X. The second active pattern 221 includes a first active portion 21, a second active portion 22, and a third active portion 23. The angle β2 formed by the second active pattern 221 and the gate line 31 towards the first end A is an obtuse angle.

In a possible implementation, the first active layer 2 may include a plurality of (vertically) linear patterns extending along the second direction. Referring to FIG. 10, a cross-sectional view along the dashed line E4F4 in FIG. 10 may be as shown in FIG. 5. The gate line 31 extends from the first end A to the second end B along the first direction X. The first active portion 21, the second active portion 22, and the third active portion 23 all extend along the second direction Y. Angles β3 formed the first active portion 21, the second active portion 22, and the third active portion 23 with the gate line 31 towards the first end A are right angles.

In a possible implementation, the first active layer 2 may include a plurality of diagonal and non-linear patterns. Referring to FIGS. 1A, 1B, and 11, a cross-sectional view along the dashed line E5F5 in FIG. 11 may be as shown in FIG. 5A. The gate line 31 extends from the first end A to the second end B along the first direction X. The first active portion 21 and the second active portion 22 both extend along the second direction Y and an extension line of the first active portion 21 does not coincide with an extension line of the third active portion 23. An angle β4 formed by at least a part of the third active portion 23 with the gate line 31 towards the first end A is an acute angle.

In a possible implementation, in conjunction with FIGS. 1A-11, a region of the first active layer 2 for lapping with the first electrode 53 may be used as the first active portion 21, a region of the first active layer 2 for lapping with the data line 41 may be used as the second active portion 22, and the remaining region of the first active layer 2 may be used as the third active portion 23. In a possible implementation, as shown in FIGS. 1A and 1B, the third active portion 23 only includes a portion extending in one direction, such as only including a diagonally extending portion. The diagonally extending portion overlaps with the gate line 31 to form at least a part of the channel region (in the embodiment of the present disclosure, the channel region may also include a region formed by overlapping of the auxiliary gate electrode G2 and the third active portion 23). In another possible implementation, as shown in FIG. 11, the third active portion 23 may include a plurality of portions extending in different directions, for example, including a diagonally extending portion, and also including a vertically extending portion. The vertically extending portion overlaps with the gate lines 31 to form at least a part of the channel region (in the embodiment of the present disclosure, the channel region may also include a region formed by the overlapping of the auxiliary gate electrode G2 and the third active portion 23).

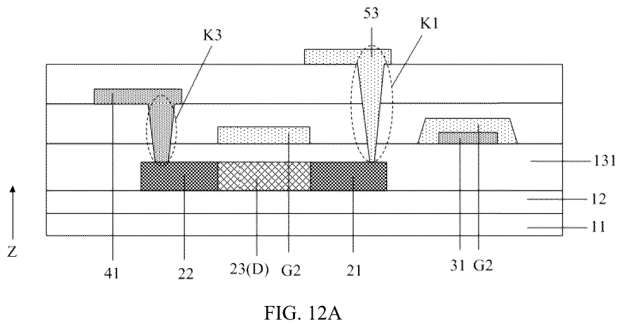

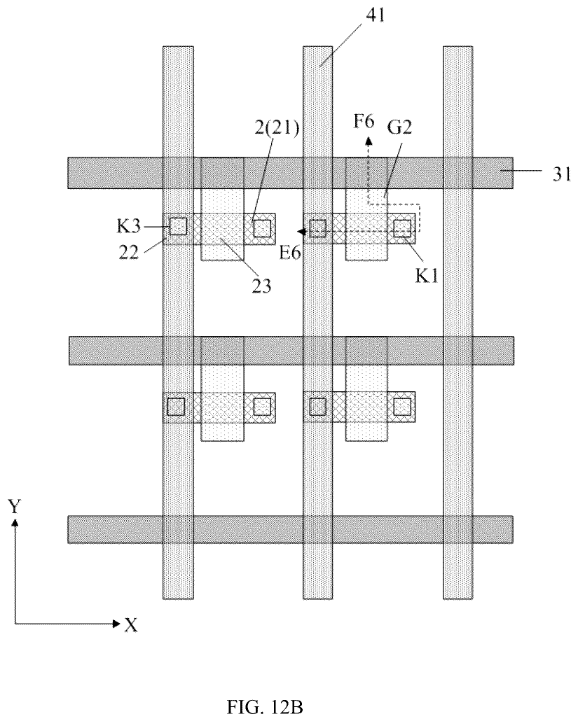

In a possible implementation, the first active layer 2 may include a (horizontal) linear pattern extending along the first direction. As shown in FIGS. 12A and 12B, FIG. 12A may be a schematic view of a cross-sectional view along the dashed line E6F6 in FIG. 12B. The first active portion 21, the second active portion 22, and the third active portion 23 all extend along the first direction X. A gap is between the orthographic projection of the first active layer 2 on the substrate 11 and the orthographic projection of the gate line 31 on the substrate 11. The third active portion 23 is in the light-transmitting region P. The gate electrode structure G includes: the auxiliary gate electrode G2 on the side of the first active layer 2 facing away from the substrate 11. The auxiliary gate electrode G2 extends along the second direction Y. The orthographic projection of the auxiliary gate electrode G2 on the substrate 11 covers the orthographic projection of the third active portion 23 on the substrate 11 and covers a part of the orthographic projection of the gate line 31 on the substrate 11. The gate electrode structure G may only include: the auxiliary gate electrode G2. The first gate electrode layer (i.e., a layer where the gate lines 31 are located) may be on the side of the first active layer 2 facing away from the substrate 11. The auxiliary gate electrode G2 is on the side of the gate line 31 facing away from the substrate 11, and is lapped in contact with the gate line 31. A part of the auxiliary gate electrode G2 overlaps with the third active portion 23 to form the channel region, and another part of the auxiliary gate electrode G2 overlaps with the gate line 31 to realize the contact lap with the gate line 31. In the embodiment of the present disclosure, a transparent auxiliary gate electrode G2 may be provided in the light-transmitting region P. The gate line 31 may be used only as a wiring and be lapped with the auxiliary gate electrode G2 in the non-light-transmitting region. Since the auxiliary gate electrode G2 and the channel region of the first active layer 2 are transparent materials, the transmittance rate will not be reduced by placing them in the light-transmitting region P, and therefore the width of the auxiliary gate electrode G2 may be appropriately enlarged so as to further ensure the transistor characteristics.

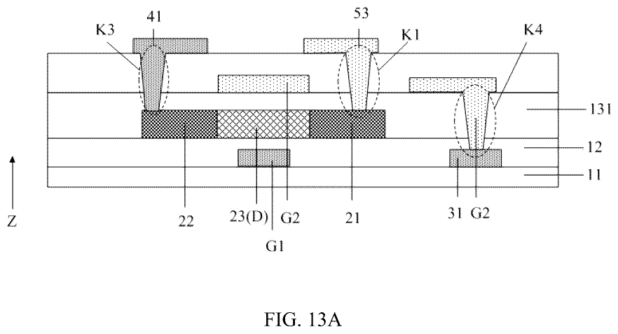

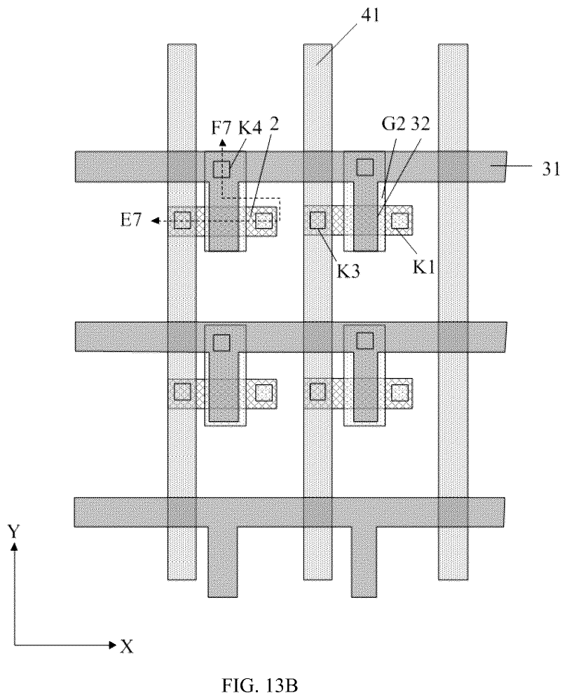

In a possible implementation, referring to FIGS. 13A and 13B, FIG. 13A may be a schematic diagram of a cross-sectional view along the dashed line E7F7 in FIG. 13B. The gate line 31 further includes a gate line branch portion 32 extending along the second direction Y.

The orthographic projection of the auxiliary gate electrode G2 on the substrate 11 covers an orthographic projection of the gate line branch portion 32 on the substrate 11. The first gate electrode layer (i.e., a layer where the gate lines 31 are located) may be on the side of the first active layer 2 towards the substrate 11. That is, the first gate electrode layer is underlaid. The gate line branch portion 32 is used as a bottom gate, and at the same time, the auxiliary gate electrode G2 is lapped with the bottom gate (the gate line branch portion 32) by punching holes (e.g., the via hole K4 in FIG. 13B). On the one hand, the gate electrode control capability can be further enhanced, in particular, for the channel portion. On the other hand, the gate line branch portion 32 is equivalent to adding a light-blocking layer to the oxide transistor to improve the photostability characteristics of the oxide transistor.

In a possible implementation, the material of the auxiliary gate electrode G2 includes: indium tin oxide, indium-doped zinc oxide, fluorine-doped tin oxide, aluminum-doped zinc oxide, or indium-doped cadmium oxide.

In a possible implementation, referring to FIG. 9A or 10, the data line 41 may include: a first data portion 411 and a second data portion 412 extending along the second direction Y and alternatively arranged along the second direction Y, and a third data portion 413 connecting the first data portion 411 to the second data portion 412 and extending along the first direction X. An extension line of the first data portion 411 does not coincide with an extension line of the second data portion 412.

In a possible implementation, as shown in FIGS. 1A, 11, 12B, and 13B, the data line 41 may also be extendable only along the second direction Y.

It should be noted that remaining film layers are abbreviated in FIGS. 5A-13B in order to clearly illustrate the specific composition of the gate electrode structure G. In a specific implementation, the array substrate shown in FIGS. 5A-13B may also include film layers shown in FIGS. 1A-4, and the conductive manner between the first electrode 53 and the first active layer 2 is also as shown in FIGS. 1A-4.

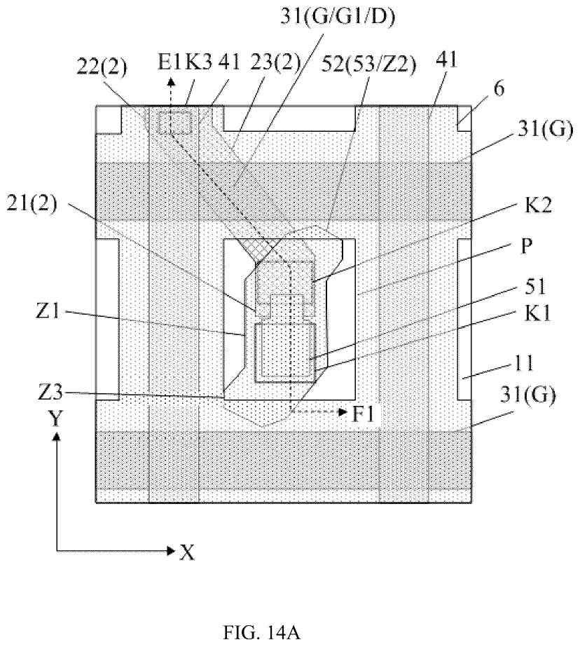

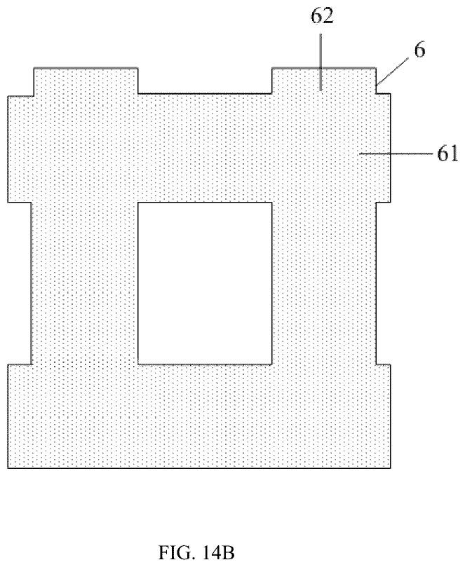

In a possible implementation, referring to FIGS. 14A and 14B, FIG. 14B may be a single film layer view of a common electrode(s) in FIG. 14A. The array substrate further includes: a common electrode(s) 6 on a side of the first electrode 5 facing away from the substrate 11. The common electrode 6 includes: a first common electrode portion 61 extending along a first direction X, and a second common electrode portion 62 extending along a second direction Y. An orthographic projection of the first common electrode portion 61 on the substrate 11 covers an orthographic projection of the gate line 31 on the substrate 11. An orthographic projection of the second common electrode portion 62 on the substrate 11 covers an orthographic projection of the data line 41 on the substrate 11. An orthographic projection of the first via hole K1 on the substrate 11 is within an orthographic projection of a region defined by the first common electrode portions 61 and the second common electrode portions 62 that are intersected on the substrate. In a possible implementation, an orthographic projection of the second via hole K2 on the substrate 11 and is also within the orthographic projection of the region defined by the first common electrode portions 61 and the second common electrode portions 62 that are intersected on the substrate. In the embodiment of the present disclosure, the first electrode 53 is designed as a strip, and the common electrode 6 is designed as a mesh. It can be seen through simulation that the array substrate of the embodiment of the present disclosure can have a significant increase in liquid crystal efficiency, which can increase the liquid crystal efficiency from 54.2% in the conventional design to 58.4%.

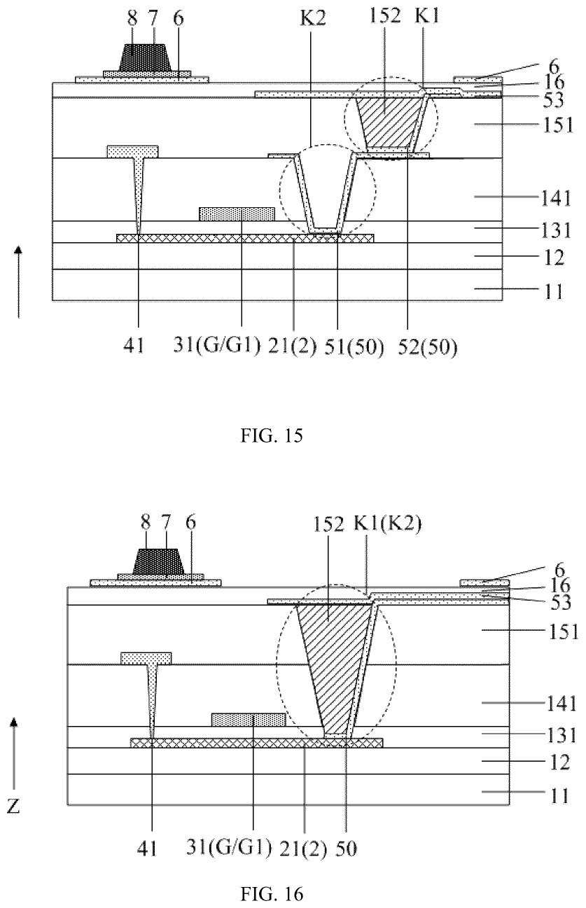

In a possible implementation, referring to FIGS. 15 and 16, the array substrate further includes: a first light-blocking layer 7 on a side of the common electrode 6 facing away from the first electrode 53 and in direct contact with the common electrode 6, and a spacer 8 on a side of the first light-blocking layer 7 facing away from the first electrode 53. The orthographic projection of the common electrode 6 on the substrate 11 covers an orthographic projection of the first light-blocking layer 7 on the substrate 11. A line width of the first light-blocking layer 7 is smaller than a line width of the common electrode 6. The orthographic projection of the first light-blocking layer 7 on the substrate 11 covers an orthographic projection of the spacer 8 on the substrate 11. A line width of the spacer 8 is smaller than the line width of the first light-blocking layer 7.

The first light-blocking layer 7 may be made of a blackened metal material, and the spacer 8 may be made of molybdenum or aluminum (i.e., a material that may be wet-etched). The first light-blocking layer 7 and the spacer 8 may be formed by one mask process. By using wet etching plus dry etching, the first light-blocking layer 7 and the spacer 8 are formed into a step shape by using the difference between the etching biases of the spacer 8 and the first light-blocking layer 7.

The thickness of the first light-blocking layer 7 may range from 30 nm to 80 nm, and the thickness of the spacer 8 may range from 0.4 um to 1 μm. The first light-blocking layer 7 may be used to block the gate lines 31 and the data lines 41 on the one hand, and reduce the resistance of the common electrode 6 on the other hand.

In a possible implementation, the orthographic projection of the first light-blocking layer 7 on the substrate 11 covers the orthographic projection of the data lines 41 on the substrate 11, and the orthographic projection of the gate lines 31 on the substrate 11. The orthographic projection of the spacer 8 on the substrate 11 covers the orthographic projection of the data line 41 on the substrate 11, and the orthographic projection of the gate line 31 on the substrate 11.

The shape of the first light-blocking layer 7 and the shape of the spacer 8 may be similar to the shape of the pattern of the common electrode 6 as shown in FIG. 14A. That is, the first light-blocking layer 7 may include a first light-blocking portion extending along the first direction X, and a second light-blocking portion extending along the second direction Y. The first light-blocking portions and the second light-blocking portions intersect to form a mesh structure. The spacer 8 may include a first spacer portion extending along the first direction X and a second spacer portion extending along the second direction Y. The first spacer portions and the second spacer portions intersect to form a mesh structure. The spacer 8 of the mesh structure may be designed with a narrower line width, which is favorable for enhancing the aperture rate of the array substrate.

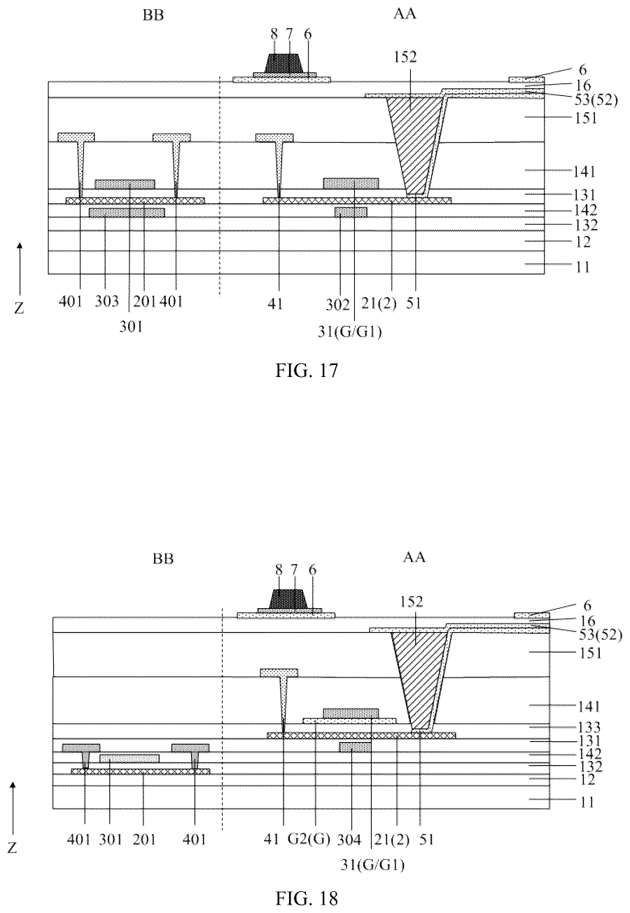

In a possible implementation, referring to FIGS. 17-20, the array substrate further includes a gate drive circuit in the non-display region BB. The gate drive circuit including: a first drive active layer 201, a first drive gate electrode 301 on a side of the first drive active layer 201 facing away from the substrate 11, and a first drive source-drain electrode 401 on a side of the first drive gate electrode 301 facing away from the first drive active layer 201.

In a possible implementation, referring to FIG. 17, the first drive active layer 201 is in the same layer and of the same material as the first active layer 2; and the first drive gate electrode 301 is in the same layer and of the same material as the first gate electrode layer. That is, the first drive gate electrode 301 is in the same layer and of the same material as the gate line 31; and the first drive source-drain electrode 401 is in the same layer and of the same material as the first source-drain electrode layer, i.e., the first drive source-drain electrode 401 is in the same layer and of the same material as the data line 41. The first active layer 2 and the first drive active layer 201 may both be oxide active layers. For example, the material of the first active layer 2 may include: an amorphous indium gallium zinc oxide (a-IGZO) material, zinc nitrogen oxide (ZnON), or indium zinc tin oxide (IZTO). In the embodiments of the present disclosure, the film layers corresponding to the display region AA and the film layers corresponding to the non-display region BB are in the same layer and of the same material. It can form the film layers of the non-display region while forming the film layers of the display region AA, which can simplify the fabrication process for the array substrate.

In a possible implementation, referring to FIG. 17, the array substrate further includes a second gate electrode layer between the substrate 11 and the first active layer 2. The second gate electrode layer includes: a first gate electrode 302 in the display region AA, and a second drive gate electrode 303 in the non-display region BB. The orthographic projection of the gate line 31 on the substrate 11 covers the orthographic projection of the first gate electrode 302 on the substrate 11. The orthographic projection of the second drive gate electrode 303 on the substrate 11 covers the orthographic projection of the first drive gate electrode 301 on the substrate 11. In the embodiments of the present disclosure, when the active layers of the transistors in the display region and the non-display region all use an oxide active layer, the transistor of the gate drive circuit in the non-display region uses an oxide double-gate electrode structure with a bottom gate size larger than a top gate size (the one-sided wrapping size may range from 0.5 μm to 2 μm), which can effectively improve the on-state current and device stability of the transistor, and the transistor in the light-transmitting region is made of a bottom gate size smaller than a top gate size (the bottom gate is reduced by 0.3 μm to 0.6 μm on one side compared to the top gate), which can avoid the effect on the aperture rate.

In a possible implementation, referring to FIG. 18, the array substrate further includes a second gate electrode(s) 304 in the display region AA and between the substrate 11 and the first active layer 2. The first drive source-drain electrode 401 is in the same layer and of the same material as the second gate electrode 304. The material of the first drive active layer 201 includes: polysilicon. In embodiments of the present disclosure, considering that the current design of the high mobility oxide gate drive circuit is not mature enough, and the size of the transistor in the gate drive circuit is large, resulting in an oversized bezel, the gate drive circuit can be designed with a low-temperature polycrystalline silicon transistor in embodiments of the present disclosure. The first drive source-drain electrode 401 of the low-temperature polycrystalline silicon transistor is in the same layer and formed by the same one mask process as the bottom gate (the second gate electrode 304) of the transistor in the display region, which can simplify the fabrication process for the array substrate. The bottom gate (second gate electrode 304) in the display region is designed to block light to the oxide first active layer 2 in the display region and improve the stability of the transistor in the display region.

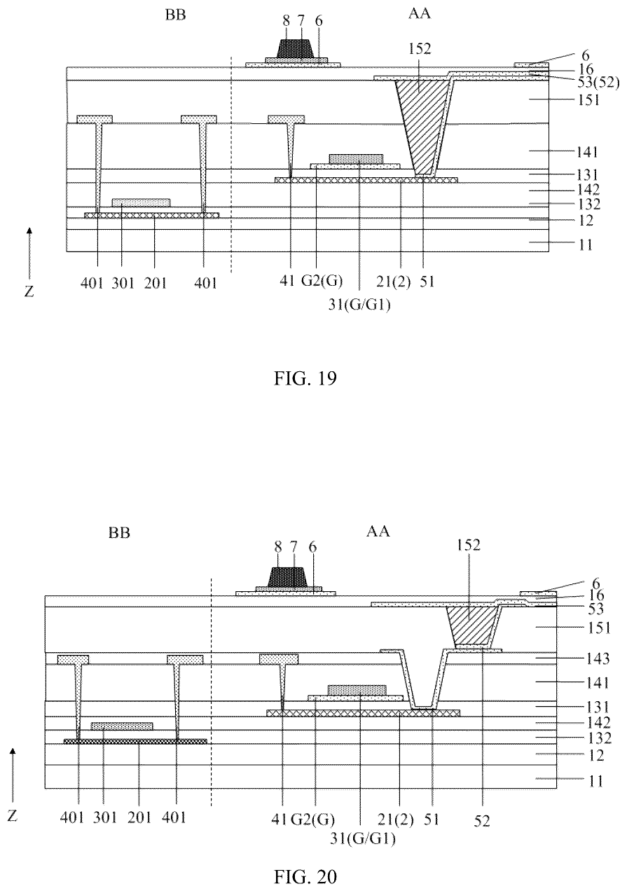

In a possible implementation, referring to FIGS. 19 and 20, the first drive source-drain electrode 401 is in the same layer and of the same material as the first source-drain electrode layer. That is, the first drive source-drain electrode 401 is in the same layer and of the same material as the data line 41. The material of the first drive active layer 201 includes: polysilicon. In the embodiments of the present disclosure, the first active layer 2 of the transistor in the display region may adopt an oxide active layer, and the transistor in the non-display region may adopt a polycrystalline silicon active layer. The oxide thin film transistor has advantages such as low leakage current, and the low-temperature polycrystalline silicon thin film transistor has advantages such as high mobility, fast charging, etc. The low-temperature polycrystalline silicon thin film transistor and the oxide thin film transistor are integrated in the array substrate to form a low-temperature polycrystalline oxide array substrate, and by utilizing the advantages of both, high resolution (Pixel Per Inch, PPI) and low-frequency drive can be achieved, power consumption can be reduced, and display quality can be improved. In addition, in the embodiments of the present disclosure, the first drive source-drain electrode 401 and the first source-drain electrode layer are in the same layer and of the same material, which can simplify the fabrication process for the array substrate.

In conjunction with FIGS. 1A-20, the array substrate further includes at least one of the following: a second interlayer dielectric layer 142 between the substrate 11 and the first active layer 2; a first gate electrode insulating layer 132 between the second interlayer dielectric layer 142 and the substrate 11; a buffer layer 12 disposed between the first gate electrode insulating layer 132 and the substrate 11; a second gate electrode insulating layer 131 between the first active layer 2 and the gate electrode portion G1; a third gate electrode insulating layer 133 between the second insulating layer 131 and the second insulating layer 141; a third interlayer dielectric layer 143 between the first connecting sub-electrode 51 and the second insulating layer 141; or a passivation layer 16 on the side of the first electrode 53 facing away from the third insulating layer 152.

In some examples, the buffer layer 12, the first insulating layer 151, the second insulating layer 141, and the third insulating layer 152 may be an inorganic insulating layer. For example, the buffer layer 12, the first insulating layer 151, the second insulating layer 141, and the third insulating layer 152 may be made of any one or more of silicon oxides (SiOx), silicon nitrides (SiNx), and silicon oxides of nitrogen (SiON) and may be a single layer, multiple layers, or a composite layer. The first gate electrode layer, the first source-drain electrode layer, the second gate, and the second source-drain electrode layer may be made of a metal material, such as any one or more of silver (Ag), copper (Cu), aluminum (Al), titanium (Ti), or molybdenum (Mo), or an alloy of the above mentioned metals, such as an aluminum-neodymium alloy (AINd) or a molybdenum-niobium alloy (MoNb), and may be of a single-layer structure or of a multilayer composite structure, such as Ti/Al/Ti, etc.

Based on the same inventive conception, an embodiment of the present disclosure further provides a display device, including a display panel as provided in the embodiments of the present disclosure.

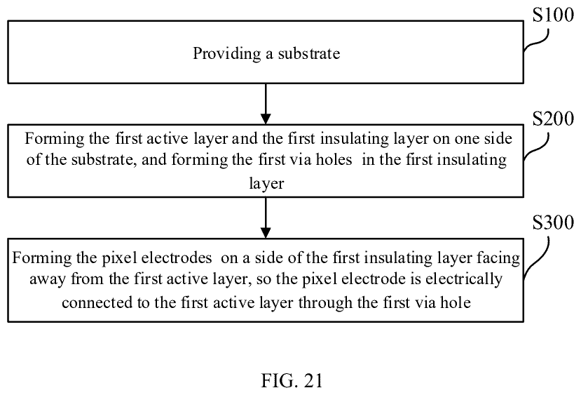

Based on the same inventive conception, referring to FIG. 21, an embodiment of the present disclosure further provides a method for fabricating the display panel as provided in the embodiments of the present disclosure, including the following.

Step S100, a substrate is provided. The substrate may be a glass substrate. A buffer layer may be first deposited on one side of the substrate, and the material of the buffer layer is selected to be SiN/SiO2, and the thickness of the buffer layer may range from 200 nm to 500 nm.

Step S200, the first active layer and the first insulating layer are formed on one side of the substrate, and the first via holes are formed in the first insulating layer. The light-resistant metal oxide active layer can be deposited, and the material can be a rare-earth-element doped material such as IZO or IGZO, which can stabilize the characteristics of the transistor under light, and a thickness ranges from 20 nm to 50 nm. Then, the second gate electrode insulating layer 131 can be deposited, the material is selected as SiO2, and the thickness ranges from 100 nm to 150 nm. Then, the first gate electrode layer is deposited, the material is selected as Al, Ti, or Mo, Cu, etc., and the thickness ranges from 200 nm~500 nm; and photolithography and etching is performed to form the shapes of the gate lines and the gate electrode portions. After that, the second insulating layer 141 is deposited, the material is selected as SiO2/SiN, a thickness ranges from 300 nm to 500 nm, and then holes are cut. Thereafter, the first source-drain electrode layer is deposited, and the material can be selected similar to that of the gate line, and then patterning is carried out. Thereafter, via holes are cut in the light-transmitting region to form second via holes K2 through which the first active layer 2 is connected. Then, the first connecting sub-electrode 51 is deposited within the second via hole K2, and patterning is carried out. Thereafter, the first insulating layer 151 is deposited to flatten the second via hole K2 in the lower layer and the metal segment difference, and then the first via hole K1 is cut in the light-transmitting region.

Step S300, the first electrodes are formed on a side of the first insulating layer facing away from the first active layer, so the first electrode is electrically connected to the first active layer through the first via hole. The second connecting sub-electrode 52 in contact with the first connecting sub-electrode 51 is deposited in the first via hole K1. Thereafter, a filling process is carried out through the third insulating layer 152. An adhesive-coating plus ashing scheme is used to ensure that the segment difference between the filled third insulating layer 152 and the first insulating layer 151 is within 0.2 μm to reduce the light leakage, and then the first electrode 53 is covered at the position of the via hole in the light-transparent region to block the electric field in the via hole, and the deposition of the passivation layer 16 and the common electrode 6 is continued to be completed. Thereafter, the first light-blocking layer 7 and the spacer 8 are deposited, the first light-blocking layer 7 is made of blackened metal material. The spacer 8 is made of metal such as Mo or Al, etc., which can be wet etched. The first light-blocking layer 7 and the spacer 8 are formed by one mask. The first light-blocking layer 7 has a thickness ranging from 30 nm to 80 nm, and the spacer 8 has a thickness ranging from 0.4 μm to 1 μm. The difference between the etching biases of the spacer 8 and the first light-blocking layer 7 is utilized to form a wrapping relationship between the first light-blocking layer 7 and the spacer 8.

In a possible implementation, with respect to step S200, forming the first active layer and the first insulating layer on the side of the substrate includes the following.

Step S211, the second insulating layer is formed on the side of the first active layer facing away from the substrate, and the second via hole(s) is formed in the second insulating layer.

Step S212, the first connecting sub-electrode is formed in a region where the second via hole is located.

Step S213, the first insulating layer is formed on the side of the second insulating layer facing away from the first active layer, and the first via hole(s) is formed in the first insulating layer.

Step S214, the second connecting sub-electrode is formed in a region where the first via hole is located.

Step S215, the third insulating layer is filled on the side of the second connecting sub-electrode facing away from the first connecting sub-electrode and in the region where the first via hole is located.

In a possible implementation, with respect to step S200, forming the first active layer and the first insulating layer on the side of the substrate includes the following.

Step S221, the second insulating layer is formed on the side of the first active layer facing away from the substrate.

Step S222, the first insulating layer is formed on the side of the second insulating layer facing away from the first active layer.

Step S223, the first via hole(s) penetrating through the first insulating layer, and the second via hole(s) penetrating through the second insulating layer and exposing a portion of the first active layer are formed by one patterning process.

Step S224, the connecting electrodes are formed in the region where the second via hole and the first via hole are located.

Step S225, the third insulating layer are filled on the side of the connecting electrodes facing away from the first active layer and in the region where the second via hole and the first via hole are located.

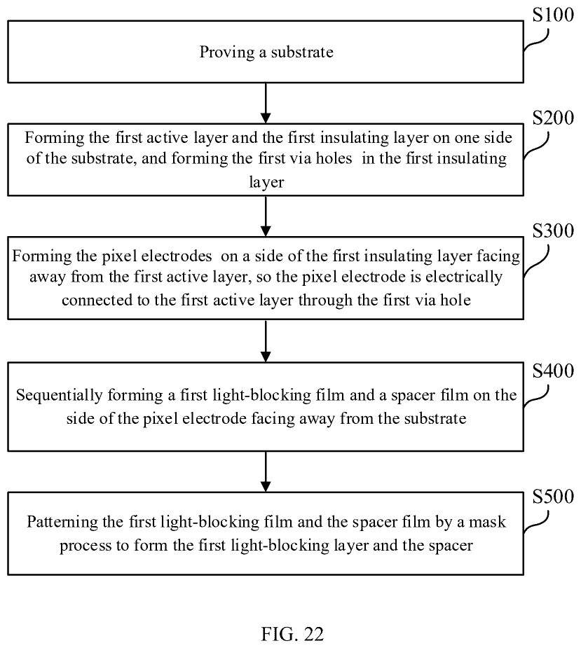

In a possible implementation, referring to FIG. 22, referring to FIG. 22, after step S300, the method for fabricating the display panel further includes the following.

Step S400, a first light-blocking film and a spacer film are sequentially formed on the side of the first electrode facing away from the substrate.

Step S500, the first light-blocking film and the spacer film are patterned by a mask process to form the first light-blocking layer and the spacer.

Although preferred embodiments of the present disclosure have been described, those skilled in the art may make additional changes and modifications to these embodiments once the basic inventive concepts are known. Therefore, the appended claims are intended to be construed to include the preferred embodiments as well as all changes and modifications that fall within the scope of the present disclosure.

Obviously, those skilled in the art may make various changes and variations to the embodiments of the present disclosure without departing from the spirit and scope of the embodiments of the present disclosure. Thus, if such modifications and variations of the embodiments of the present disclosure fall within the scope of the claims of the present disclosure and their technical equivalents, the present disclosure is intended to encompass such modifications and variations.

1. An array substrate, comprising:
a substrate;
a first active layer on a side of the substrate; and
a gate electrode structure on a side of the first active layer facing away from the substrate;
wherein the gate electrode structure comprises an auxiliary gate electrode, an orthographic projection of the auxiliary gate electrode on the substrate has an overlapping region with an orthographic projection of the first active layer on the substrate, and a thickness of the auxiliary gate electrode in a direction perpendicular to the substrate ranges from 20 nm to 200 nm.

2. The array substrate according to claim 1, further comprising: a plurality of gate lines extending in a first direction, a plurality of auxiliary gate lines extending in the first direction, and a plurality of data lines main bodies of which extend in a second direction; wherein an orthographic projection of the plurality of auxiliary gate lines on the substrate has an overlapping region with an orthographic projection of the plurality of gate lines on the substrate; and
the gate electrode structure further comprises: a gate electrode portion; the gate line comprises the gate electrode portion, and the auxiliary gate line comprises the auxiliary gate electrode; an orthographic projection of the auxiliary gate electrode on the substrate covers an orthographic projection of the gate electrode portion on the substrate, and covers at least one of regions on two sides of the gate electrode portion in the second direction; and a thickness of the gate electrode portion in the direction perpendicular to the substrate is greater than a thickness of the auxiliary gate electrode in the direction perpendicular to the substrate, and a ratio of the thickness of the gate electrode portion in the direction perpendicular to the substrate to the thickness of the auxiliary gate electrode in the direction perpendicular to the substrate ranges from 1 to 20.

3. The array substrate according to claim 2, wherein a width al of the auxiliary gate electrode in the second direction satisfies a following relational formula:
1.5≤a1/a2≤2, wherein a2 represents a width of the gate electrode portion in the second direction:
wherein the width al of the auxiliary gate electrode in the second direction satisfies a following relational formula:
0.5μm≤a1−a2|≤1.5μm.

4. (canceled)

5. The array substrate according to claim 2, wherein the auxiliary gate line comprises: a first auxiliary portion, and a second auxiliary portion electrically connected to the first auxiliary portion; wherein the second auxiliary portion of an N^{th} auxiliary gate line is on a side of the first auxiliary portion of the N^{th} auxiliary gate line facing an (N+1)^{th} auxiliary gate line, wherein N is a positive integer; and
an orthographic projection of the first auxiliary portion of the N^{th} auxiliary gate line on the substrate coincides with an orthographic projection of an N^{th} gate line on the substrate, and an orthographic projection of the second auxiliary portion of the N^{th} auxiliary gate line on the substrate does not overlap with the orthographic projection of the N^{th} gate line on the substrate.

6. The array substrate according to claim 2, wherein an N^{th} auxiliary gate line has a first outer edge facing away from an (N+1)^{th} gate line, and an N^{th} gate line has a second outer edge facing away from the (N+1)^{th} gate line, wherein N is a positive integer; and
the first outer edge coincides with the second outer edge; or
the second outer edge is on a side of the first outer edge facing away from the (N+1)^{th} gate line

7. (canceled)

8. The array substrate according to claim 6, further comprising: a first electrode on a side of the gate electrode structure facing away from the substrate, a first insulating layer between the first electrode and the first active layer, and a second insulating layer between the first insulating layer and the first active layer;
the first active layer comprises: a first active portion, a second active portion, and a third active portion between the first active portion and the second active portion; and an orthographic projection of the second active portion on the substrate overlaps with a part of an orthographic projection of the data line on the substrate; and
the first insulating layer is provided with a first via hole, and the first electrode is electrically connected to the first active portion at least through the first via hole; and the second insulating layer is provided with a third via hole, and the data line is electrically connected to the second active portion at least through the third via hole.

9. The array substrate according to claim 8, wherein the N^{th} gate line has a third outer edge facing the (N+1)^{th} gate line, and the N^{th} gate line satisfies a following relational formula:
b1>b2>0, wherein b1 represents a minimum distance between an orthographic projection of the third outer edge of the N^{th} gate line on the substrate and an orthographic projection of a center point of the first via hole on the substrate in the second direction, and b2 represents a minimum distance between an orthographic projection of the second outer edge of the N^{th} gate line on the substrate and an orthographic projection of a center point of the third via hole on the substrate in the second direction; or
the N^{th} gate line has a third outer edge facing the (N+1)^{th} gate line, and the N^{th} gate line satisfies a following relational formula:
b3>b4>0, wherein b3 represents a minimum distance between an orthographic projection of the third outer edge of the N^{th} gate line on the substrate and an orthographic projection of the first via hole on the substrate in the second direction, and b4 represents a minimum distance between an orthographic projection of the second outer edge of the N^{th} gate line on the substrate and an orthographic projection of the third via hole on the substrate in the second direction.

10. (canceled)

11. The array substrate according to claim 8, wherein an area of an orthographic projection of the first via hole on the substrate is greater than an area of an orthographic projection of the third via hole on the substrate.

12. The array substrate according to claim 2, wherein the auxiliary gate line is provided with a convex portion protruding in the second direction; and an orthographic projection of the convex portion on the substrate has an overlapping region with the orthographic projection of the first active layer on the substrate.

13. The array substrate according to claim 12, further comprising: a first electrode on a side of the gate electrode structure facing away from the substrate, and a first insulating layer between the first electrode and the first active layer;
the first active layer comprises: a first active portion; the first insulating layer is provided with a first via hole, and the first electrode is electrically connected to the first active portion at least through the first via hole; and
in a direction parallel to the first direction, a minimum distance between the first via hole and the convex portion is greater than or equal to 0.

14. The array substrate according to claim 13, further comprising: a second insulating layer between the first insulating layer and the first active layer;
the first active layer further comprises: a second active portion, and a third active portion between the first active portion and the second active portion; an orthographic projection of the second active portion on the substrate overlaps with a part of an orthographic projection of the data line on the substrate; and the second insulating layer is provided with a third via hole, and the data line is electrically connected to the second active portion at least through the third via hole; and
in the direction parallel to the first direction, a minimum distance between the third via hole and the convex portion is greater than or equal to 0.

15. The array substrate according to claim 8, wherein an orthographic projection of the first via hole on the substrate is within an orthographic projection of a region defined by the gate lines and the data lines that are intersected on the substrate, and the first electrode is electrically connected to the first active layer through the first via hole.

16-27. (canceled)

28. The array substrate according to claim 1, wherein the gate electrode structure comprises: a gate electrode portion; the auxiliary gate electrode is on two sides of the gate electrode portion in the second direction; and an orthographic projection of the gate electrode portion on the substrate does not overlap with the orthographic projection of the auxiliary gate electrode on the substrate.

29. The array substrate according to claim 28, wherein a maximum spacing of the orthographic projection of the auxiliary gate electrode on the substrate in the second direction is greater than or equal to a maximum spacing of the orthographic projection of the gate electrode portion on the substrate in the second direction.

30. The array substrate according to claim 2, wherein the gate line extends from a first end of the gate line to a second end of the gate line in the first direction; and the first active layer comprises a first active group and a second active group alternatively arranged in the second direction;
the first active group comprises: first active patterns extending in a third direction and sequentially arranged in the first direction, the first active patterns each comprise a first active portion, a second active portion, and a third active portion, and an angle formed by the first active pattern with the gate line towards the first end is an acute angle; and
the second active group comprises: second active patterns extending in a fourth direction and sequentially arranged in the first direction, the second active patterns each comprise a first active portion, a second active portion, and a third active portion, and an angle formed by the second active pattern with the gate line towards the first end is an obtuse angle.

31. The array substrate according to claim 8, wherein the gate line extends from a first end of the gate line to a second end of the gate line in the first direction; and
the first active portion, the second active portion, and the third active portion all extend in the second direction, and angles formed by the first active portion, the second active portion, and the third active portion with the gate line towards the first end are right angles.

32. The array substrate according to claim 2, wherein the gate line extends from a first end of the gate line to a second end of the gate line in the first direction; and
a first active portion and a second active portion both extend in the second direction, an extension line of the first active portion does not coincide with an extension line of the third active portion, and an angle formed by at least a part of the third active portion with the gate line towards the first end is an acute angle.

33. The array substrate according to claim 8, wherein the first active portion, the second active portion, and the third active portion all extend in the first direction, and wherein a gap is between the orthographic projection of the first active layer on the substrate and the orthographic projection of the gate line on the substrate; and
the gate electrode structure comprises: the auxiliary gate electrode on a side of the first active layer facing away from the substrate, the auxiliary gate electrode extends in the second direction, and the orthographic projection of the auxiliary gate electrode the substrate covers an orthographic projection of the third active portion on the substrate and covers a part of the orthographic projection of the gate line on the substrate;
wherein the first gate electrode layer is on a side of the first active layer facing the substrate; the gate line further comprises a gate line branch portion extending in the second direction; and
the orthographic projection of the auxiliary gate electrode on the substrate covers an orthographic projection of the gate line branch portion on the substrate.

34-35. (canceled)

36. The array substrate according to claim 28, wherein the data line comprises: a first data portion and a second data portion extending in the second direction and alternatively arranged in the second direction, and a third data portion connecting the first data portion to the second data portion and extending in the first direction, wherein an extension line of the first data portion does not coincide with an extension line of the second data portion.

37. (canceled)

38. A display panel, comprising the array substrate according to claim 1.

39. (canceled)
